(19) United States
(12) Patent Application Publication
(10) Pub. No.: US 2023/0227992 A1
(43) Pub. Date: Jul. 20, 2023

(54) ELECTROFILL FROM ALKALINE ELECTROPLATING SOLUTIONS

(71) Applicant: Lam Research Corporation, Fremont, CA (US)

(72) Inventors: Lee J. Brogan, Newberg, OR (US); Matthew Martin Huie, Tigard, OR (US); Yi Hua Liu, Sherwood, OR (US); Jonathan David Reid, Sherwood, OR (US)

(21) Appl. No.: 17/995,243

(22) PCT Filed: Apr. 6, 2021
(86) PCT No.: PCT/US2021/026028

§ 371 Date: Sep. 30, 2022

Related U.S. Application Data
(60) Provisional application No. 63/006,500, filed on Apr. 7, 2020.

(51) Int. Cl. C25D 3/38; C25D 21/10; C25D 5/34; C25D 21/12

(52) U.S. Cl. CPC C25D 3/38; C25D 21/10; C25D 5/34; C25D 21/12

(57) ABSTRACT

Disclosed are alkaline electrodeposition solutions and apparatus and methods for using such solutions to electroplate metal. During electroplating, the solutions may produce superconformal fill of metal in features such as features having a critical dimension of about 20 nm or less. The metal electroplating process may be used during integrated circuit fabrication. For example, it may be used to fill trenches and vias in partially fabricated integrated circuits. The electroplated metal may be copper. The copper may be electroplated on a substrate material that is less noble than copper.

### INCORPORATED BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

As fabricated integrated circuit features get smaller, there is less room for thicker, robust seed layers to support copper electroplating, but because of its low resistivity, copper metal is still used for many applications such as damascene fill in back end of line processes. In some implementations, copper is electroplated on material that is less noble than copper, such as cobalt.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Some aspects of this disclosure pertain to methods of electroplating a metal into features of a substrate. Such methods may be characterized by the following operations: contacting a substrate with an electroplating solution, and electroplating copper metal from the electroplating solution into features of the substrate. In some implementations, the electroplating solution comprises:
an aqueous solution of pH greater than 7,
about 0.1 to 60 g/L copper salt dissolved in the aqueous solution,
a copper (II) complexing ligand, and
combination of a suppressor and an accelerator selected from the group consisting of (i) a polyallylamine (suppressor) and thiourea (accelerator); (ii) polyallylamine (suppressor) and ammonium thiocyanate (accelerator), and (iii) saccharin (suppressor) and thiourea (accelerator).

In some implementations, the electroplating solution comprises:
an aqueous solution of pH greater than 7,
about 0.1 to 60 g/L copper salt dissolved in the aqueous solution,
a copper (II) complexing ligand,
an accelerator comprising a thiocyanate salt; and
a suppressor.

The electroplating operation may be implemented as a superconformal fill of the copper metal into the features of the substrate. In some cases, the electroplating operation is performed while rotating the substrate in the electroplating solution. In some cases, the electroplating operation is performed while flowing the electroplating solution through a cell containing the substrate.

In certain embodiments, prior to contacting the substrate with the electroplating solution, the method additionally includes an operation of annealing the substrate in inert or reducing atmosphere at a temperature of about 30 to 600 degrees C. for a period of about 30 seconds to one hour. In certain embodiments, prior to contacting the substrate with the electroplating solution, the method additionally includes an operation of annealing the substrate in the presence of a remote reducing plasma while heated the substrate a temperature about 30 C to 600 C for a period of about 30 seconds to one hour. In certain embodiments, prior to contacting the substrate with the electroplating solution, the method additionally includes an operation of contacting the substrate with a pretreatment bath for about 1 to 600 seconds. In certain embodiments, the pretreatment bath has composition that is different from the composition of the electroplating solution. In certain embodiments, the method additionally includes electrically polarizing the substrate in the pretreatment bath. In certain embodiments, the pretreatment bath contains no constituent chemicals not also present in the electroplating solution. In some implementations, after a pretreatment period of time, the method additionally includes modifying the composition of the pretreatment bath to produce the electroplating solution.

In some embodiments, the electroplating operation fills features of the substrate having a critical dimension of about 20 nm or less. In some embodiments, the features of the substrate comprise a diffusion barrier that is about 1 to 5 nm thick. As an example, the diffusion barrier comprises a tantalum nitride. In certain embodiments, the features of the substrate comprise a conductive liner that is about 1 to 5 nm thick. As an example, the conductive liner comprises cobalt, molybdenum, titanium, or any combination thereof.

In certain embodiments, after contacting the substrate with the electroplating solution, the method additionally includes an operation of holding the substrate at an electrical potential of about 0 to about −1.5V relative to a copper pseudoreference electrode. As an example, the substrate is held at the electrical potential of about 0 to −1.5V relative to a copper pseudoreference electrode for a time of about 0 to about 10 seconds. In certain embodiments, after contacting the substrate with the electroplating solution, the method additionally includes an operation of controlling current so that about 0 A flows between the substrate and the electroplating solution.

In certain embodiments, the operation of electroplating copper metal comprises controlling current to provide a current density on an electroplating face of the substrate of about 0.25 mA/cm² to about 40 mA/cm². In certain embodiments, the operation of electroplating copper metal comprises controlling current between the substrate and the electroplating solution such that the current increases from a low value to a high value or decreases from a high value to low value. For example, the current may be controlled to provide a current density on an electroplating face of the substrate of about 1 to about 60 mA/cm² for a period of about 0.1 to about 10 seconds, and then decreasing the current density on the electroplating face of the substrate. In certain embodiments, the operation of electroplating copper metal comprises controlling current between the substrate and the electroplating solution using a series of current pulses.

In certain embodiments, the operation of electroplating copper metal comprises controlling the potential of the substrate.

Certain aspects of this disclosure pertain to an electroplating solution that may be characterized by the following components:
an aqueous solution of pH greater than 7;
about 0.1 to 60 g/L Cu(II) supplied as a copper salt dissolved in the aqueous solution;
a copper (II) complexing ligand; and
combination of a suppressor and an accelerator selected from the group consisting of (a) a polyallylamine (suppressor) and thiourea (accelerator); (b) polyallylamine (suppressor) and ammonium thiocyanate (accelerator), and (c) saccharin (suppressor) and thiourea (accelerator).

Certain aspects of this disclosure pertain to an electroplating solution that may be characterized by the following components:
an aqueous solution of pH greater than 7;
about 0.1 to 60 g/L Cu(II) supplied as a copper salt dissolved in the aqueous solution;
a copper (II) complexing ligand;
an accelerator comprising a thiocyanate salt; and
a suppressor.

Some electroplating solutions additionally include a pH adjustment agent or buffer sufficient to maintain the pH above 7 during electroplating of copper from the electroplating solution.

Some electroplating solutions additionally include a leveler. Some electroplating solutions additionally include a sacrificial oxidant.

In some electroplating solutions, the copper (II) complexing agent is present in the aqueous solution at concentration sufficient to prevent copper hydroxide precipitation.

Some electroplating solutions additionally include a copper (I) complexing ligand. In some examples, the electroplating solution includes a component that reduces the ability of the copper (I) ligand to prevent Cu(I) reduction during electroplating.

These and other features of the disclosure will be presented in more detail below with reference to the associated drawings.

### BRIEF DESCRIPTION OF THE DRAWINGS

FIG. 1 is a flow chart of an example process that may be employed to electroplate metal in features of a partially fabricated integrated circuit.

FIGS. 2-4 are schematic diagrams of examples of electroplating cells and systems containing electroplating cells for performing methods in accordance with disclosed embodiments.

FIG. 5 is an example of fill profiles illustrating the effect of electrical waveforms, particularly one having an initial current pulse.

FIG. 6 is an example showing electron micrographs of microfabricated trench cross sections partially plated with copper from alkaline electroplating solutions having various combinations of accelerator and suppressor.

FIG. 7A-C are examples illustrating results of two electrochemical techniques for additive screening.

### DETAILED DESCRIPTION

Introduction and Context

This disclosure pertains to alkaline electrodeposition solutions and to apparatus and methods for using such solutions to electroplate metal. In certain embodiments, the solutions can produce superconformal fill of metal in small features, e.g., features having a critical dimension of about 20 nm or less. The metal electroplating process may be used during integrated circuit fabrication. For example, it may be used to fill trenches and vias in partially fabricated integrated circuits. In certain embodiments, the metal is copper. In some implementations, copper is electrodeposited on a substrate material that is less noble than copper.

Various embodiments of this disclosure pertain to electrofill of features in one or more layers of dielectric material. Some embodiments pertain to forming conductive lines in partially fabricated electronic devices. In some cases, the electrofill is performed in a damascene process that fills features that have a critical dimension of about 20 nm or smaller, e.g., 14 nm or smaller.

In some implementations, features to be electrofilled (e.g., trenches and/or vias in a dielectric material) contain a diffusion barrier that may be about 1 to 5 nm thick. In some cases, the diffusion barrier comprises a TaN. In some cases, the diffusion barrier is deposited by CVD. In some implementations, the features to be electrofilled also include a conductive liner that may be about 1 to 5 nm thick. In some cases, the conductive liner comprises cobalt, molybdenum, titanium, or any combination thereof. The conductive liner may comprise a metal that easily forms an oxide that can be dissolved in acid. Use of such metal liners presents a challenge to superconformal fill in conventional acid electroplating solutions.

As fabricated parts get smaller, there is less room for a relatively thick and robust conductive liner to support copper electroplating. However, due to its low resistivity, copper remains the primary current carrying metal in many integrated circuit designs. As mentioned, for some damascene applications, the critical dimension is 14 nm or smaller, while the diffusion barrier and conductive liner are each about 1 to 5 nm thick.

The native oxide formed on conductive liners may be quickly removed by typical acid electroplating solutions and cannot be recovered. This problem is worsened when the substrate material is less noble than copper, such as is the case with cobalt. The copper ions participate in an exchange reaction with cobalt or other less noble liner material. The effects of the acid and exchange reaction results in reduced liner thickness. Copper that is electroplated on such liners may deposit only at some locations and not others.

In some implementations, the electroplating process is conducted by applying a cathodic protective potential during immersion. However, this does not always provide sufficient protection.

In some implementations, an alkaline electroplating solution is used because an alkaline solution is less likely to dissolve conductive liners such as cobalt. Further, certain electroplating solutions employ one or more compounds that complex copper ions. The resulting complexed copper ions are less likely to participate in an exchange reaction with the cobalt metal or other conductive liner metal.

However, even with the protections afforded by alkaline electroplating solutions such as these, superconformal fill may remain a challenge. An appropriate choice of electroplating additives, including an accelerator and a complementary suppressor and/or leveler, for superconformal fill has been elusive.

Aspects of this disclosure pertain to electrofill process es using (a) defined electroplating solution compositions, (b) pretreatment of the substrate liner, and/or (c) defined electroplating process parameters. Each of these will be treated herein. In certain embodiments, disclosed alkaline electrofill solutions permit preservation of substrate metal, even if its surface has been partially or fully converted to native oxide. In certain embodiments, the electroplating solutions, apparatus, and processes described herein provide good nucleation of copper on a conductive liner such as a cobalt liner.

In certain embodiments of this disclosure, a copper electrofill solution includes: (a) an alkaline copper ion plating solution, (b) complexing agents for Cu(II) and/or Cu(I), (c) a buffer to maintain alkalinity, and (d) electroplating additives (e.g., an accelerator and a suppressor).

In some alkaline electroplating solutions, an accelerator behaves similarly to 3-mercapto-1-propanesulfonic acid (MPS) and/or bis(3-sulfopropyl)disulfide (SPS) in an acid solution during superconformal electrofill of copper. Such behavior may include strong adherence to the copper metal surface during deposition. Additionally, the accelerator does not substantially degrade or become substantially incorporated into the growing electrofilled copper layer. Unfortunately, it has been found that SPS and MPS may not work adequately in some alkaline solutions.

A suppressor in an alkaline electroplating solution may behave similarly to suppressors in acid solutions during superconformal electrofill of copper. However, any suppressor used in an alkaline electroplating solution should be compatible with the accelerator in that solution. A leveler in an alkaline electroplating solution may operate similarly to levelers in acid solutions during superconformal electrofill of copper. However, any leveler used in an alkaline electroplating solution should work in conjunction with the accelerator in that solution.

In certain embodiments, an alkaline electroplating solution comprises one or more complexing agents for copper(I) and/or copper(II) ions. In certain embodiments, an alkaline electroplating solution comprises one or more sacrificial oxidants. A sacrificial oxidant may protect the conductive liner by having reduction potentials that allow them to compete with copper deposition and produce lower than unity current efficiency

In certain embodiments, copper electroplating in an alkaline solution is preceded by treating the conductive liner on features of a substrate in a way that protects the liner from removal upon contact with the alkaline electrofill solution. Such pretreatments may involve contacting the liner with a wet environment and/or a dry environment that chemically reduces the liner or otherwise modifies the liner to resist attack by the alkaline electroplating solution.

In certain embodiments, the pretreatment is a dry process that chemically reduces metal oxide on the liner and thereby increases the amount of elemental metal in the liner. Examples of dry pretreatments include, e.g., high temperature anneals and exposure to reducing plasmas (e.g., hydrogen-containing plasmas).

In certain embodiments, the pretreatment is a wet protection that reduces metal oxide on the liner or otherwise protects the metal liner from the alkaline solution. The wet pretreatment may be performed in the electroplating cell (in situ) or outside the electroplating cells (ex situ). In certain embodiments, a wet pretreatment comprises applying a reducing potential to the substrate to chemically reduce a liner's oxide while it is present in the solution. In some embodiments, wet reduction of oxide is performed in solution having no metal.

In certain embodiments, depositing copper metal from an alkaline electroplating solution comprises applying current pulses and/or a voltage ramp to the substrate on which the copper is electroplated. In some cases, the voltage ramp is applied initially during the electroplating process.

Any one or more of the following features may be used alone or in any combination with any of the others.
1) Accelerator/suppressor combination for electroplating copper from an alkaline electroplating solution onto, e.g., a conductive liner comprising a metal that is less noble than copper;
2) Use of leveler mediated diffusion-based mechanism to electrofill features;
3) Cu(II) and/or Cu(I) ligands in an alkaline electroplating solution;
4) Sacrificial oxidants in an alkaline electroplating solution;
5) Use of pulsed electroplating (e.g., pulse electrical current applied to the electroplating cell)
6) Use of ramped electrical current waveforms during electroplating;
7) Control of mass transport (e.g. by controlling the rotation rate of a rotating electrode and/or the electroplating solution flow rate to an electroplating cell); optionally change the mass transport conditions during plating to, e.g., optimize fill across a variety of structure sizes;
8) Use of a wet pretreatment solution; optionally perform pretreatment in-situ on a substrate in an electroplating cell, and replacing a pretreatment bath with an electroplating solution; and
9) Use of a dry pretreatment to condition a conductive liner before plating.

The following detailed description describes electrochemical plating, also referred to as “electroplating” or “plating” for short. In certain embodiments, electroplating fills features in partially fabricated semiconductor devices on semiconductor substrates. In this description, the term “semiconductor wafer” or “semiconductor substrate,” or simply “substrate” refers to a substrate that has semiconductor material anywhere within its body, and it is understood by one of skill in the art that the semiconductor material does not need to be exposed. The semiconductor substrate may include one or more dielectric and conductive layers formed over the semiconductor material. A wafer used in the semiconductor wafer may be a circular-shaped semiconductor substrate, which may have a diameter of 200 mm, 300 mm, or 450 mm, for example. However, one skilled in the art will appreciate that suitable alternative implementations of that described herein exist, and that the disclosed electroplating operations may be conducted on work pieces of various shapes and sizes, and which are made from various materials. In addition to semiconductor wafers, other work pieces that may take advantage of the disclosed implementations include various articles such as electronically controlled displays, backplanes for such displays, and the like. In some embodiments, the wafer may be glass or another non-semiconductor material.

Electroplating Solutions

In various aspects, electroplating solutions of this disclosure are alkaline and contain copper. In certain embodiments, the substrate electroplated with an alkaline electroplating solution contains a material that is less noble than the copper. For example, the substrate may contain a cobalt liner. Compared to an acid electroplating solution, an alkaline electroplating solution may not aggressively attack a less noble material on the substrate. An alkaline electroplating solution may allow a passivating layer of native oxide to remain on the surface of the less noble material. During electroplating or during a wet pretreatment, a native oxide can be electrochemically reduced in situ rather than being quickly dissolved by the electrolyte. In some embodiments, an alkaline electroplating solution comprises a species that complexes copper ions and thereby reduces the thermodynamic driving force for galvanic corrosion of the substrate by copper.

As mentioned, in certain embodiments, the electroplating solution is alkaline. Therefore, in some cases, the pH of the electroplating solution is from about 7 to 14. In some cases, the pH of the electroplating solution is from about 8-10.

As mentioned, in certain embodiments, the electroplating solution contains copper. In some embodiments, the range of copper concentrations possible is limited by solubility and/or the complexer species used in the electroplating solution. In certain embodiments, the concentration of copper ions in the electroplating solution is about 0.1 to about 2 g/L. In such embodiments, the copper ion may be supplied in the form of copper sulfate. In some cases, the concentration of copper ions in the electroplating solution is about 0.4 to about 1 g/L.

Alkaline, copper-containing electroplating solutions may contain any of various additives. Some of these are described here.

One class of additive is molecules which serve as suppressors, requiring increased polarization before copper will reduce onto the substrate from solution. Another class contains molecules or elements which serve as accelerators, which reduce the polarization required to reduce copper from solution relative to the action of suppressors. Another class contains molecules or ions which serve as levelers, which decrease the activity of accelerators and allow accelerated surfaces to return to a more suppressed state. A further class includes molecules or ions which serve as Cu(II) complexers, stabilizing the copper ions in solution. A further class includes molecules or ions which serve as Cu(I) complexers, stabilizing the reaction intermediate of the Cu(II)→Cu reaction and thus increasing its rate. There may be some overlap in these classes, as Cu(I) complexers which increase the reaction rate and decrease polarization can, in some contexts, also be considered accelerators relative to certain suppressors. Yet another class are molecules or ions which serve to modify or maintain the pH in an alkaline region. Still another class includes molecules or ions that are sacrificial oxidants which have electrode reduction potentials such that they can effectively compete with copper deposition and produce lower than unity current efficiency.

Suppressing molecules or “suppressors” are generally those which make copper reduce less readily onto the substrate. One mechanism by which this may occur is through chemisorption of a molecule on the substrate surface which either sterically hinders the approach of Cu (11) ions or occupies reaction sites on the substrate. In cases in which the substrate is not a copper film, the chosen suppressor interacts with both the unplated substrate surface and the plated copper film.

Suppressors (either alone or in combination with other electroplating solution additives) are surface-kinetic polarizing compounds that lead to a significant increase in the voltage drop across the substrate-electrolyte interface, especially when present in combination with a surface chemisorbing halide (e.g., chloride or bromide). In some cases, the halide acts as a chemisorbed-bridge between the suppressor molecules and the substrate surface. The suppressor both (1) increases the local polarization of the substrate surface at regions where the suppressor is present relative to regions where the suppressor is absent (or present at a relatively lower concentration), and (2) increases the polarization of the substrate surface generally. The increased polarization (local and/or general) corresponds to increased resistivity/impedance and therefore slower plating at a particular applied potential.

Suppressors may be relatively large molecules, and in some instances they are polymeric, such as polyether (e.g., paraformaldehyde, polyethylene oxide (PEO), polypropylene oxide (PPO), polyethylene glycol (PEG), polypropylene glycol (PPG), other general polyalkylene glycol (PAG) polymers, copolymers (including block copolymers) of any of these, and the like). These polymers and copolymers may be further functionalized, with the functional groups that may improve solubility or interaction with the substrate. Some examples of suppressors include polyethylene oxides and polypropylene oxides with sulfur and/or nitrogen-containing functional groups. The suppressors can have linear chain structures or branch structures or both. A particular class of suppressor molecules includes the organic chemisorption corrosion inhibitors. Suppressor molecules with various molecular weights may co-exist in a suppressor solution.

Due in part to suppressors' large size, the diffusion of these compounds into a recessed feature can be relatively slow compared to other electroplating solution components.

In some cases, suppressors are not significantly incorporated into the deposited film, though they may slowly degrade over time by electrolysis or chemical decomposition in the electroplating solution.

Aside from chemical structural characteristics, suppressor may be characterized by certain electrochemical or other physical properties. These include the speed at which the suppressor exhibits an effect on polarization and the strength of the polarization effect. Because suppressors increase polarization, they will make the deposition potential (cathodic potential) more negative. The magnitude of the negative change in the deposition potential is a measure of the polarization strength of the suppressor. One way to measure a suppressor's properties is to conduct an experiment that plates metal (e.g., copper) onto a metal electrode (e.g., cobalt or copper). The experiment begins by plating metal using a plating solution that does not contain the suppressor under consideration. The plating may be conducted galvanostatically and the plating potential (e.g., the potential of the cathode) may be monitored. After plating for a period of time (e.g., to a point where the system is at steady state), the suppressor in question is introduced to the plating solution. During and after this introduction, a constant current is applied and the electrode potential is measured. The delay until a measurable change in voltage is detected indicates the speed of the suppressor's effect. The magnitude of the change in voltage (regardless of how soon it occurs) indicates the “strength” of the suppressor's effect. In certain embodiments, the plating continues for about 5 to 10 minutes after the suppressor is introduced. If there is no detectable potential change during the period, the suppressor is characterized as slow or having no effect. If the change happens nearly immediately (e.g., within about 1 seconds after the suppressor is added), the suppressor is characterized as fast. In certain embodiments, a suppressor is deemed to have a strong response if it makes the deposition potential more negative by at least about 200 mV compared to the potential exhibited under the same conditions but without any electroplating additives. In certain embodiments, a suppressor is deemed to have a weak response if it makes the deposition potential more negative by no more than about 50 mV.

The results in the following table were obtained using an additive addition method common to the industry. The electrode is first polarized in an electrolyte solution containing metal ions, pH buffer, and complexers (aliphatic amines, such as, ethylene diamine) until a baseline constant current is achieved. After this potential is established, the suppressor is added and the magnitude and rate of polarization change are used to characterize the suppressor as strong/weak and fast/slow, respectively. If accelerator is subsequently tested, it is added after the suppressor reaches a steady state and the further magnitude and rate of polarization change is used to characterize the accelerator as strong/weak and fast/slow, respectively.

TABLE 1

| Suppressors | Appearance | Strength | Speed |
|---|---|---|---|
| Polyethylene glycol (PEG) | | Very Weak | Slow |
| Polyvinylpyrrolidone (PVP) | Dark | Weak | Slow |
| Benzotriazole (BTA) | Hazy | Strong | Fast |
| o-benzoic sulfimide | Bright | Very/Strong | Very Fast |
| Poly(diallyldimethylammonium) | Bright | Weak | Fast |
| chloride (PDMAC) | | | |
| Polyethyleneimine (PEI) | Bright | Medium | Slow |
| Polyacrylamide (PAM) | Bright | Weak | Slow |
| Poly(2-ethyl-2-oxazolone) (P2EO) | Bright | Weak | Fast |
| Benzethonium chloride | Very Dark | Strong | Fast |
| Polyallylamine (PAL) | Hazy | Strong | Slow |
| Thonzonium bromide | | Strong | Slow |
| Cocamidopropyl betaine (CAPB) | Dark | Weak | Fast |
| 3-(1-pyridino)-1-propanesulfonate (31PS) | Bright | Weak | Fast |
| Sodium Lauryl Sulfate | Hazy | Very/Weak | Slow |
| Imidazole | Dark, Rough | Very/Strong | Slow |
| 1-benzylimidazole | Bright | Weak | Fast |
| Benzimidazole (BI) | Dark | Medium | Very Slow |
| 3-Pyridine sulfonic acid (3PS) | Bright | Weak | Slow |
| 2-aminoethanesulfonic acid | Bright | Weak | Slow |
| 3-amino-1-propanesulfonic acid | | Weak | Medium |
| Janus B Green | | Weak | |
| 2-mercaptobenzimidazole (MBI) | Dark | Strong | |
| Caffeine | | Very Weak | |
| 2-amino-5-(ethylthio)-1,3,4- | Dark | Weak | Slow |
| thiadiazole (2A5E) | | | |
| 2-thiazoline-2-thiol (2T2T) | Dark/Dull | Very Strong | Fast |
| 6-amino-2-mercaptobenzothiazole (AMBT) | Dark | Weak | Slow |
| 2-mercaptobenzothiazole (MET) | Dark | Very Strong | Slow |
| Hexadecyltrimethylammonium bromide | Dark | Weak | Slow |
| (CTAB) | | | |
| 2,2′-dipyridyldisulfide (DPDS) | Dark | Weak | Slow |
| Purine | Dark | Strong | Fast |
| 2-aminopyridine (2AP) | Dark | Strong | Fast |
| 3-hydroxypyridine-4-sulfonic acid (3HPS) | Dark | Weak | Fast |

In certain embodiments, any one or more of the suppressors listed above is used in an alkaline electroplating solution. In certain embodiments, a polyallylamines ([C₃H₅NH₂]ₙ) or a structurally related polymer is used as a suppressor in an alkaline electroplating solution.

Accelerator molecules can make copper reduce more readily onto the substrate relative to a suppressed surface, e.g., a surface having suppressor species attached. It is believed that accelerators (either alone or in combination with other electroplating solution additives) locally reduce the polarization effect associated with the presence of suppressors, and thereby locally increase the electrodeposition rate. Accelerator molecules may be used based in part on their ability to sustain higher rates of plating in areas where these high rates begin (vis-à-vis area where suppressor dominates the polarization characteristic).

Electrochemically, accelerators decrease in the magnitude of polarization required to deposit copper onto a suppressed substrate. Since suppressor molecules are more inhibiting than accelerators, one possible mechanism of action of suppressors involves competition with suppressor for binding sites, resulting in higher current densities in those area in which suppressor is supplanted by accelerator. Another possible mechanism of action is through the stabilization of a Cu(I) reaction intermediate, which may reduce polarization of a region of substrate to a level even lower in magnitude than that of an unsuppressed surface. Thus, some Cu(I) ligands may act as a form of accelerator. Both these potential mechanisms of action are possible in parallel.

The reduced polarization effect is most pronounced in regions of the substrate surface where the accelerator is most concentrated (i.e., the polarization is reduced as a function of the local surface concentration of adsorbed accelerator). Although the accelerator may become strongly adsorbed to the substrate surface and may be generally laterally-surface immobile as a result of the plating reactions, in some embodiments, the accelerator is generally not significantly incorporated into the film. In such cases, the accelerator may remain on the surface as metal is deposited. As a recess is filled, the local accelerator concentration increases on the surface within the recess. Accelerators tend to be smaller molecules and exhibit faster diffusion into recessed features, as compared to suppressors.

Accelerators may be characterized by certain electrochemical or other physical properties. These include the speed at which the accelerator exhibits an effect on polarization and the strength of the accelerator's depolarization effect. Because accelerators decrease polarization, they will make the deposition potential (cathodic potential) more positive. The magnitude of the negative change in the deposition potential is a measure of the depolarizing strength of the accelerator. One way to measure an accelerator's properties is to conduct an experiment that plates metal (e.g., copper) onto a metal electrode (e.g., cobalt or copper). The experiment begins by plating metal using a plating solution that does not contain the accelerator under consideration. The plating may be conducted galvanostatically and the plating potential (e.g., the potential of the cathode) is monitored. After plating for a period of time (e.g., to a point where the system is at steady state), the accelerator in question is introduced to the plating solution. During and after this introduction, a constant current is applied and the electrode potential is measured. The delay until a measurable change in voltage is detected indicates the speed of the accelerator's effect. The magnitude of the change in voltage (regardless of how soon it occurs) indicates the “strength” of the accelerator's effect. In certain embodiments, the plating continues for about 5 to 10 minutes after the accelerator is introduced. If there is no detectable potential change during the period, the accelerator is characterized as slow or having no effect. If the potential change occurs nearly immediately (such as within 1 second), the accelerator is characterized as very fast. In certain embodiments, an accelerator is deemed to have a strong response if it makes the deposition potential more positive by at least about 400 mV compared to a solution that contains suppressor and electrolyte but no accelerator. In certain embodiments, an accelerator is deemed to have a weak response if it makes the deposition potential more negative by no more than about 50 mV.

A list of accelerators useful in certain alkaline of electroplating solutions of this disclosure is presented in the table below. The results in the table were obtained by using two types of experiment. One is additive addition method common to the industry. The electrode is first polarized in an electrolyte solution containing metal ions, pH buffer, and complexers (ethylene diamine) until a baseline constant current is achieved. After this potential is established, the suppressor is added and the magnitude and rate of polarization change are used to characterize the suppressor as strong/weak and fast/slow, respectively. If accelerator is subsequently tested, it is added after the suppressor reaches a steady state and the further magnitude and rate of polarization change is used to characterize the accelerator as strong/weak and fast/slow, respectively. The second type of experiment is cyclic voltammetry (CV). When a CV of the fully composed solution is compared to that of a solution containing only the base electrolyte, the difference between the polarization at a given current can be found. The more polarization required, the stronger the suppression.

TABLE 2

| Accelerators | Film | Strength | Speed |
|---|---|---|---|
| SPS | Bright | Weak | Slow |
| MPS | Bright | Strong | Fast |
| Chloride (e.g., NaCl, KCl, or HCl) | Bright | Weak | Fast |
| Bromide (e.g., NaBr, KBr, or HBr) | Bright | Very Strong | Very Fast |
| Ammonia | Bright | | |
| Thiourea | Dark | Very Strong | Very Fast |
| Ammonium Thiocyanate (ATC) | Bright | Very Strong | Medium |
| Potassium Thiocyanate | Hazy | Very Strong | Fast |
| 1,2,4-Triazole | Dark | Strong | Fast |
| 1H-benzotriazole sulfonic acid (BTAS) | Dark | Strong | Fast |
| Safranin O | Bright | Weak | Fast |
| Ammonium Thiosulfate | Hazy | Very Strong | Fast |
| Ammonium persulfate | Bright | Medium | Fast |
| l,3,4-Thiadiazole-2,5-dithiol (TDDT) | Hazy | Very Strong | Medium |
| Sodium Cyanate | Bright | Very weak | Fast |
| Potassium Triflate | Bright | None | |
| 2-mercapto-5- | Dark | Strong | Fast |
| benzimidazolesulfonic | | | |
| acid (MBIS) | | | |
| Iodide (e.g., NaI, KI, and HI) | Dark | Strong | Fast |
| 3-mercaptopropionic acid (3MPA) | Dark | Medium | Medium |
| 2-mercaptoethanol (2ME) | Dark | Weak | Medium |
| Poly(N-isopropylacrylamide) (PIPAM) | Hazy | Very Weak | Medium |
| 3-amino-5-mercapto-1,2,4-triazole (AMT) | Hazy | Strong | Slow |
| 5-amino-2-mercaptobenzimidazole (AMBI) | Bright/Red | Medium | Fast |
| Thiazole | Bright | Strong | Slow |
| 2-mercaptothiazole (MT) | Dark | Strong | Fast |
| Rhodanine | Bright | Very Strong | Fast |

As indicated, an alkaline electroplating solution may include an accelerator that is a halide (iodide, bromide, chloride, and/or fluoride). In various embodiments, halide ion is provided to the electroplating solution as a salt such as a salt of an alkali metal, e.g., NaCl, NaBr, NaI, KCl, KBr, KI, and the like. Halide ion may also be provided by any of a variety of salts or as an acid such as HCl, HBr, and HI. Of course, when the acid is neutralized, a salt that is determined by the base, which may be, for example, one of the pH adjustors described below.

In addition, or alternatively, an accelerator may be a pseudohalide. Examples of pseudohalides include cyanides, cyaphides, isocyanides, hydroxides, bisulfides, cyanates, isocyanates, fulminates, thiocyanates, isothiocyanates, hypothiocyanates, selenocyanates, azides, nitrites, tetracarbonylcobaltates, trinitromethanides, tricyanomethanides, and trifluoromethanesulfonates (triflates). Any of these halides and pseudohalides may be provided in a compound containing any cation or organic species. One example of a cation is an ammonium ion such as NH₄ or a substituted ammonium ion such as a quaternary ammonium ion. In various embodiments, a thiocyanate such as ammonium thiocyanate or an alkali metal thiocyanate is present as an accelerator.

Leveling molecules may act by limiting the depolarizing effect of an accelerating molecule. Levelers may perform this function especially in exposed portions of a substrate, such the field region of a wafer being processed, and at the side walls of a feature. A leveler may act by desorbing or displacing the accelerator, preventing it from effectively competing with a suppressor for binding sites, burying it in the plated film, or chemically degrading it. The local concentration of levelers is determined to some degree by mass transport. It is believed that in many cases the leveler reacts or is consumed at the substrate surface at a rate that is at or near a diffusion limited rate, and therefore, a continuous supply of leveler may maintain uniform plating conditions over time.

There are two potential roles of a leveler in disclosed alkaline electroplating solutions. First is in controlling overplating, so that features which begin to experience accelerated fill do not overshoot so much that the final uniformity of the plated part is too poor to allow for good downstream planarization. Levelers performing this role may act principally on surface structures having geometries that protrude away from the surface. This action smooths the surface of the electrodeposited layer. The second is a fill mechanism in which leveler deactivates accelerator preferentially on the field and toward the top of the feature, enhancing the ability of the system to produce and sustain superconformal fill.

Leveler compounds are generally classified as such based on their electrochemical function and impact and do not require specific chemical structure or formulation. However, levelers often contain one or more nitrogen-containing compounds, such as amines, imides, amides or imidazoles, and may also contain sulfur functional groups. Certain levelers include one or more five and six member rings and/or conjugated organic compound derivatives. Nitrogen groups may form part of the ring structure. In amine-containing levelers, the amines may be primary, secondary or tertiary alkyl amines. Furthermore, the amine may be an aryl amine or a heterocyclic amine. Example amines include, but are not limited to, dialkylamines, trialkylamines, arylalkylamines, triazoles, imidazole, triazole, tetrazole, benzimidazole, benzotriazole, piperidine, morpholines, piperazine, pyridine, oxazole, benzoxazole, pyrimidine, quonoline, and isoquinoline. Imidazole and pyridine may be especially useful. Other examples of levelers include Janus Green B and Prussian Blue.

Generally, levelers may fall within the category of nitrogen-containing heterocyclic compounds. A heterocycle compound has one or more heterocyclyl moieties, as defined herein, such as aromatic heterocycles (e.g., having one or more nitrogen atoms), bicyclic heterocycles (e.g., aromatic bicyclic heterocycles), various aliphatic heterocycles, and the like.

In certain embodiments, the heterocycle is a cyclic amine. An example cyclic amine can have a formula of NR¹R²R³, wherein R¹ and R², taken together with the nitrogen atom to which each are attached, form a heterocyclyl, and wherein R³ is hydrogen, hydroxyl, aliphatic, haloaliphatic, haloheteroaliphatic, heteroaliphatic, aromatic, aliphatic-aromatic, heteroaliphatic-aromatic, or any combinations thereof. Example cyclic imines are provided in the list below.

In another embodiment, the heterocycle is a cyclic amide. An example cyclic amide can have a formula of R³—C(O)NR¹R², wherein R¹ and R², taken together with the nitrogen atom to which each are attached, form a heteroaliphatic or heterocyclyl group, as defined herein, and wherein R³ is, independently, aliphatic, haloaliphatic, haloheteroaliphatic, heteroaliphatic, aromatic, aliphatic-aromatic, heteroaliphatic-aromatic, or any combinations thereof, or wherein R¹ and R³, taken together with the nitrogen atom to which R¹ is attached, form a heteroaliphatic or heterocyclyl group, as defined herein, and wherein R² independently, hydrogen, aliphatic, haloaliphatic, haloheteroaliphatic, heteroaliphatic, aromatic, aliphatic-aromatic, heteroaliphatic-aromatic, or any combinations thereof; or wherein each of R¹ and R² is, independently, hydrogen, aliphatic, haloaliphatic, haloheteroaliphatic, heteroaliphatic, aromatic, aliphatic-aromatic, heteroaliphatic-aromatic, or any combinations thereof, and wherein R³ is optionally substituted heterocyclyl or optionally substituted alkyl-heterocyclyl.

In another embodiment, the heterocycle is a N-heterocyclic carbene or cyclic thioalkyl amino carbene (e.g., as described further below).

Non-limiting examples of nitrogen-containing heterocycles include optionally substituted imidazole, optionally substituted triazole, optionally substituted tetrazole, optionally substituted pyrazole, optionally substituted imidazoline, optionally substituted pyrazoline, optionally substituted imidazolidine, optionally substituted pyrazolidine, optionally substituted pyrrole, optionally substituted pyrroline, optionally substituted pyrrolidine, optionally substituted succinimide, optionally substituted thiazolidinedione, optionally substituted oxazolidone, optionally substituted hydantoin, optionally substituted pyridine, optionally substituted piperidine, optionally substituted pyridazine, optionally substituted piperazine, optionally substituted pyrimidine, optionally substituted pyrazine, optionally substituted triazine, optionally substituted oxazine, optionally substituted morpholine, optionally substituted thiazine, optionally substituted thiomorpholine, optionally substituted cytosine, optionally substituted thymine, optionally substituted uracil, optionally substituted thiomorpholine dioxide, optionally substituted indene, optionally substituted indoline, optionally substituted indole, optionally substituted isoindole, optionally substituted indolizine, optionally substituted indazole, optionally substituted benzimidazole, optionally substituted azaindole, optionally substituted azaindazole, optionally substituted pyrazolopyrimidine, optionally substituted purine, optionally substituted benzisoxazole, optionally substituted anthranil, optionally substituted benzisothiazole, optionally substituted benzoxazole, optionally substituted benzthiazole, optionally substituted benzthiadiazole, optionally substituted adenine, optionally substituted guanine, optionally substituted tetrahydroquinoline, optionally substituted dihydroquinoline, optionally substituted dihydroisoquinoline, optionally substituted quinoline, optionally substituted isoquinoline, optionally substituted quinolizine, optionally substituted quinoxaline, optionally substituted phthalazine, optionally substituted quinazoline, optionally substituted cinnoline, optionally substituted naphthyridine, optionally substituted pyridopyrimidine, optionally substituted pyridopyrazine, optionally substituted pteridine, optionally substituted benzoxazine, optionally substituted quinolinone, optionally substituted isoquinolinone, optionally substituted carbazole, optionally substituted acridine, optionally substituted phenazine, optionally substituted phenoxazine, optionally substituted phenothiazine, optionally substituted phenoxathiine, optionally substituted quinuclidine, optionally substituted azaadamantane, optionally substituted dihydroazepine, optionally substituted azepine, optionally substituted diazepine, optionally substituted thiazepine, optionally substituted azocane, optionally substituted azocine, optionally substituted azonane, optionally substituted azecine, etc. Optional substitutions include any substituent group such as alkoxy, amide, amine, thioether, thiol, acyloxy, silyl, cycloaliphatic, aryl, aldehyde, ketone, ester, carboxylic acid, acyl, acyl halo, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

Heterocycles can also include cations and/or salts of any of these. In some embodiments, cationic forms include an optionally substituted alkyl attached to a nitrogen atom of a heterocycle. Example cationic forms include thiazolium, as well as salts thereof. Heterocycles can include one or more substituents (e.g., any described herein for aryl or alkyl, such as amine, alkyl, oxo, etc.). Example substituted heterocycles include N-methyl pyrrolidone, N-methylimidazole, 2,6-lutidine, and 4-N,N-dimethylaminopyridine. In some embodiments, the heterocycle includes two or more heteroatoms (e.g., two or more of N, O, and/or S).

In certain embodiments, the leveler is a heterocyclic aromatic compound. A heterocyclic, nitrogen-containing aromatic compound is an aromatic compound that includes a 5-, 6- or 7-membered ring, unless otherwise specified, containing one, two, three, or four non-carbon heteroatoms (e.g., including nitrogen and, optionally, one or more other heteroatoms independently selected from the group consisting of oxygen, phosphorous, sulfur, or halo).

In some cases, a heterocyclic aromatic compound is methylated. In some cases, a heterocyclic aromatic compound follows the Hückel 4n+2 rule. In some cases, the additive is a halogen-substituted aromatic compound. A halogen-substituted aromatic compound is an aromatic compound that includes at least one halogen bonded to the aromatic ring. As used herein, halogen or halo refers to F, Cl, Br, or I.

In some embodiments, the leveler is a heterocyclic aliphatic compound. As used herein, “aliphatic” means a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. A heterocyclic aliphatic compound is an aliphatic compound that includes a 5-, 6- or 7-membered ring, unless otherwise specified, containing one, two, three, or four non-carbon heteroatoms (e.g., at least one nitrogen atom and, optionally, one or more other heteroatoms independently selected from the group consisting of oxygen, phosphorous, sulfur, or halo).

Leveler compounds may also include alkoxide groups, such as methoxide, ethoxide groups. For example, the leveler may include a general backbone similar to that found in polyethylene glycol or polyethylene oxide, with fragments of amine functionally inserted over the chain (e.g., Janus Green B). Leveler compounds may also include epoxides. Example epoxides include, but are not limited to, epihalohydrins such as epichlorohydrin and epibromohydrin, and polyepoxide compounds. Polyepoxide compounds having two or more epoxide moieties joined together by an ether-containing linkage may be especially useful. Some leveler compounds are polymeric, while others are not. Example polymeric leveler compounds include, but are not limited to, polyethylenimine, polyamidoamines, and reaction products of an amine with various oxygen epoxides or sulfides. One example of a non-polymeric leveler is 6-mercapto-hexanol. Another example leveler is polyvinylpyrrolidone (PVP).

Levelers that may be used in alkaline electroplating solutions of this disclosure include many which have been used in acid electroplating solutions for conformal fill applications, as well as other compounds. Examples are provided in Table 3.

Superconformal Fill

In the superconformal fill mechanism, a recessed feature on a plating surface tends to be plated with metal from the bottom to the top of the feature, and inward from the side walls towards the center of the feature. Controlling the relative deposition rates within the feature and in the field region achieves uniform filling and avoids incorporating voids into the electrofilled features. The three types of additives described above are beneficial in accomplishing superconformal fill, each working to selectively increase or decrease the polarization at the substrate surface.

After the substrate is immersed in electrolyte, the suppressor adsorbs onto the surface of the substrate, especially in exposed regions such as the field region. At the initial plating stages, there may be a substantial differential in suppressor concentration between the top and bottom of a recessed feature. This differential is present due to the relatively large size of the suppressor molecule and its correspondingly slow transport properties. Over this same initial plating time, it is believed that accelerator accumulates at a low, substantially uniform concentration over the entire plating surface, including the bottom and side walls of the feature. Because the accelerator diffuses into features more rapidly than the suppressor, the initial ratio of accelerator to suppressor within the feature (especially at the feature bottom) is relatively high. The relatively high initial accelerator:suppressor ratio promotes rapid plating from the bottom of the feature upwards and from the sidewalls inwards. Meanwhile, the initial plating rate in the field region is relatively low due to the lower ratio of accelerator:suppressor. Thus, in the initial plating stages, plating occurs relatively faster within the feature and relatively slower in the field region.

As plating continues, the feature fills with metal and the surface area within the feature is reduced. Because of the decreasing surface area and the accelerator substantially remaining on the surface, the local surface concentration of accelerator within the feature increases as plating continues. This increased accelerator concentration within the feature helps maintain the differential plating rate beneficial for superconformal fill.

In the later stages of plating, particularly as overburden deposits, the accelerator may build up in certain regions (e.g., above filled features), resulting in local faster-than-desired plating. Leveler may be used to counteract this effect. The surface concentration of leveler is greatest at exposed regions of a surface (i.e., not within recessed features) and where convection is greatest. It is believed that the leveler displaces accelerator, increases the local polarization and decreases the local plating rate at regions of the surface that would otherwise be plating at a rate greater than at other locations on the deposit. In other words, the leveler tends, at least in part, to reduce or remove the influence of an accelerating compound at the exposed regions of a surface, particularly at protruding structures. Without leveler, a feature may tend to overfill and produce a bump. Therefore, in the later stages of superconformal fill plating, levelers are beneficial in producing a relatively flat deposit. Note that superconformal fill is sometimes referred to as “bottom-up fill.”

The use of suppressor, accelerator and leveler, in combination, may allow a feature to be filled without voids from the superconformal and from the sidewalls-inward, while producing a relatively flat deposited surface.

As explained, an alkaline, copper ion-containing electroplating solution may include a combination of an accelerator and a suppressor. In some embodiments, the combination includes a strong and fast (from a polarization perspective) accelerator is coupled with strong and fast suppressor. In some embodiments other combinations are used. These include, for example, a strong and slow accelerator used in combination with a strong and fast suppressor, and a weak and fast accelerator used in combination with a weak and slow suppressor. In certain embodiments, the suppressor is strong enough to polarize the electrode surface (the field region) and prevent plating there, and the accelerator either acts more quickly or more strongly in the feature to encourage plating there. The descriptions of strong, fast, weak, and slow polarization effects, and corresponding tests for establishing these effects, as described above may apply to the combinations identified here. Thus, for example, suppressor and accelerators characterized as strong, weak, fast, slow in Tables 1 and 2 may apply to the combinations here.

Complexer

A copper (II) complexer may be used in an alkaline electroplating solution. Such complexer may prevent or reduce the amount of copper hydroxide precipitation. In certain embodiments, the complexer prevents copper hydroxide precipitation when the copper ion concentration is relatively high such as upon preparation of the electroplating solution or while the solution is dosed with a make-up solution comprising copper ions. This complexer may also a role in achieving higher polarization and reducing the redox activity of the Cu(II) ion, which may help preserve a substrate which is less noble than copper. For example, a copper (II) complexer in an alkaline electroplating solution may prevent or reduce the amount of cobalt removed from a cobalt liner during contact with an alkaline electroplating solution. Copper (II) ligands that may be used in an alkaline electroplating solution include, but are not limited to, straight chained, cyclic, or polycyclic polyamines, amino carboxylic acids, alkanolamines, oxycarboxylic acids, cyclic acid-imide compounds, and organic phosphonic acids. Some examples of copper(II) complexers are listed in Table 3.

A copper (I) complexer may be serve any one or more of various roles, some depending on the electrofill mechanism pursued. For example, a Cu(I) ligand may stabilize Cu(I) as an intermediate in the copper (II) reduction reaction, causing the reduction reaction to occur more readily. In this role, a Cu(I) ligand may act as an accelerator. In another example, a Cu (I) ligand may further stabilize the Cu(I) intermediate, such that instead of encouraging the full reduction reaction form Cu (II) to Cu metal it instead interrupts it. The stabilized Cu(I) can then diffuse away from the electroplating copper surface. In this role the Cu(I) ligands have similar functionality to a sacrificial oxidant (i.e., they hinder the copper deposition more significantly in the field region than in the features). Copper (I) ligands that may be used in an alkaline electroplating solution include, but are not limited to, molecules and ions considered “soft.” Soft ions are those which have a low charge relative to their volume, such as Cu(I) in contrast to ions with a high concentration of charge, such as H⁺. Such ions include some halides, pseudohalides, cyclic acid-imide compounds, and compounds containing sulfur functional groups such as thiols, sulfides, disulfides, sulfinic and sulfonic acids, thiocyanates, isothiocyanates, thials (RC(S)H), and sulfones. Some examples of copper(I) complexers are listed in Table 3.

Base

As mentioned, alkaline electroplating solutions may help preserve the passivating oxide on a substrate metal during immersion into the electroplating solution. By comparison to acidic electroplating solutions, alkaline electroplating solutions may slow or prevent a substrate metal and/or an oxide thereof from dissolving. As examples, two kinds of bases may be used to produce and maintain an alkaline electroplating solution. The first of these are bases, particularly hydroxide-containing bases, which may be used to adjust the pH of the electroplating solution into a desired range. Strong bases may include, but are not limited to, potassium hydroxide and sodium hydroxide. Weak bases include ammonium hydroxide, tetramethyl ammonium hydroxide, tetraethyl ammonium hydroxide, and other quaternary ammonium hydroxides. The second class of bases of interest are buffer systems capable of maintaining the electroplating solution passively in the pH region of interest. A combination of active electroplating solution management with a stronger base and passive electroplating solution management with a buffering system will result in a more manufacturable process. Some examples of buffers and pH adjusting species are listed in Table 3.

Sacrificial Oxidants

Sacrificial oxidants are species that are more readily reduced from the solution than Cu(II). Sacrificial oxidants may therefore provide a side reaction pathway to produce less than 100% copper deposition current efficiency. These ions or molecules can generate fill through a mechanism of differential current efficiency. In such a mechanism a concentration gradient or an activity gradient is established between the feature and the field of the substrate such that the ratio of sacrificial oxidant reduction to copper ion reduction is greater on the field than within the feature. The concentration or activity gradient can be generated through diffusion or the use of molecules that encourage or suppress the side reaction such as catalysts and inhibitors, respectively.

Generally, sacrificial oxidants are species having reduction potentials more positive than the reduction potential of Cu(II) in the solution being examined. A sacrificial oxidant may be chosen by comparing the reduction potential of Cu(II), in the alkaline electroplating solution under consideration, with the standard reduction potentials of a candidate sacrificial oxidant in the solution phase and selecting the candidate if it has a reduction potential in the desired range. The Cu(II) standard reduction potential is 0.339 V, but when complexed by a strong ligand this potential decreases substantially. The standard reduction potential of Cu(II) with ethylenediamine is −0.119 V and with ethylenediaminetetraacetic acid (EDTA) is −0.216 V. Thus, reactions with solution phase reactants and products and standard reduction potentials more positive than −0.216 V are of potential interest as sacrificial oxidants. Some examples of sacrificial oxidants are listed in Table 3. Any one or any combination of these may be used in an alkaline electroplating solution.

TABLE 3

| Role | Purpose | Chemicals of Interest |
|---|---|---|
| Suppressor | Adsorb to the substrate | 1,1-dioxo-1,2-benzothiazol-3-one (saccharin), |
| Examples | and make copper reduce | poly(allylamine) |
| | less readily from the | 1-benzylimidazole, benzimidazole (BI) |
| | electroplating solution | 2-Mercaptobenzimidazole |
| | | 2-aminoethanesulfonic acid (taurine) |
| | | 2-Mercapto-5-benzimidazolesulfonic acid |
| | | 3-(1-pyridino)-1-proanesulfonate (31PS) |
| | | 3-Pyridine sulfonic acid (3PS) |
| | | Ascorbic acid |
| | | Benzotriazole |
| | | Butyl alcohol - ethylene oxide-propylene oxide |
| | | copolymers |
| | | Carboxymethylcellulose |
| | | Cocamidopropyl betaine (CAPB) |
| | | Dodecyl hydrogen sulfate (Lauryl sulfate) |
| | | Ethylene oxide-propylene oxide copolymers |
| | | Imidazole |
| | | Mercaptobenzotriazole |
| | | Nonylphenolpolyglycol ether |
| | | Octandiolbis (polyalkylene glycol ether) |
| | | Octanol polyalkylene glycol ether |
| | | Oleic acid polyglycol ester |
| | | Poly (2-ethyl-2-oxazoline) (P2EO) |
| | | Poly(diallyldimethyl ammonium chloride) (PDMAC), |
| | | Benzethonium |
| | | Polyacrylamide (PAM) |
| | | Polyallylamine (PAL) |
| | | Polyetheleneimine (PEI) |
| | | Polyethylene glycol |
| | | Polyethylene glycoldimethyl ether |
| | | Polyethylene oxide |
| | | Polyethylene propylene glycol |
| | | Polyoxypropylene glycol |
| | | Polypropylene glycol |
| | | Polyvinyl alcohol |
| | | Polyvinylpyrrolidone (PVP) |
| | | Stearic acid polyglycol ester |
| | | Stearyl alcohol polyglycol ether |
| | | Succinic acid |
| | | Thonzonium |
| | | Tolytriazole |
| | | Urea |
| | | [heterocyclic nitrogen compounds] |
| | | [sulfur containing compounds] |
| | | [acetylenic compounds] |
| | | Tryptamine |
| | | Caffeine |
| Accelerator | Make copper reduce more | 1-benzylimidazole (BI) |
| Examples | readily on a suppressed | 1H-benzotriazole sulfonic acid (BATS) |
| | surface; meant to | 1-sodium-3-mercaptopropane-1-sulfonate |
| | accumulate at the base of | 3-(benzothiazolyl-s-thio)propyl sulfonic acid sodium |
| | features. May overlap | salt |
| | with Cu (I) complexers | 3,7-dimethyl-10-phenylphenazin-10-ium-2,8- |
| | | diamine; chloride (Safranin O) |
| | | 3-mercapto-1-propanesulfonic acid (MPS) |
| | | 3-mercapto-ethyl propylsulfonic acid (3- |
| | | sulfoethyl)ester |
| | | 3-mercapto-ethylsulfonic acid sodium salt |
| | | 3-mercapto-propylsulfonic acid (3-sulfopropyl) ester |
| | | 3-mercaptopropylsulfonic acid sodium salt |
| | | Bis(3-sulfopropyl)-disulfide (SPS) |
| | | Bis-sulfopropyl disulfide |
| | | Bromide ion (e.g., NaBr, KBr, and HBr) |
| | | Chloride (e.g., NaCl, NaCl, and HCl) |
| | | Iodide (e.g., NaI, NaI, and HI) |
| | | Carbonic acid- dithio-o-ethyl ester-s-ester |
| | | Carbonic acid-dithio-o-ethylester-s-ester |
| | | Chloride ion |
| | | N,N-dimethyl-dithiocarbamic acid (-3-sulfopropyl) |
| | | ester |
| | | N,N-dimethyl-dithiocarbamic acid(3-sulfoethyl)ester |
| | | N-dimethyldithiocarbamic acid (DPS) |
| | | Persulfate salts including ammonium persulfate |
| | | Pyridinium ethyl sulfobetaine |
| | | Pyridinium propyl sulfobetaine |
| | | Thiocyanate salts including ammonium thiocyanate |
| | | Thiosulfate salts including ammonium thiosulfate |
| | | Thiourea′ |
| Leveler | Decrease accelerator | 1-(2-hydroxyethyl)2-imidazolidinethion |
| Examples | activity, thereby helping | 2-mercaptothiazoline |
| | to smooth deposited film. | 4-mercaptopyridine |
| | May aid in fill in | Acrylamide |
| | diffusion controlled | Alkylated polyalkyleneimines |
| | regimes. | Benzoxazole |
| | | Butyne 1:4 diol and derivatives |
| | | Coumarin |
| | | Ethylene thiourea |
| | | Imidazole |
| | | Isoquinoline |
| | | Morpholine |
| | | Organic sulfonates |
| | | Oxazole |
| | | Piperazine |
| | | Piperidine |
| | | Polyethylene glycol |
| | | Pyridine |
| | | Quinoline |
| | | Sodium naphthalene 2-sulphonate |
| | | Substituted amines |
| | | Tetrazole |
| | | Thiourea |
| | | Triazole |
| Buffers and | Maintain the alkalinity of | Sodium hydroxide |
| pH adjuster | the electroplating | Potassium hydroxide |
| Examples | solution. There is some | Ammonium hydroxide |
| | overlap with complexing | Monoethanolamine |
| | agents. | Diethanolamine |
| | | Triethanolamine |
| | | Ethelene diamine |
| | | Diethylenetriamine |
| | | Triethylenetetramine |
| | | N-(2-Acetamido)-2-aminoethanesulfonic acid (ACES, |
| | | pH 6.1-7.5) |
| | | Piperazine-N,N′-bis(2-ethanesulfonic acid (PIPES, |
| | | pH 6.1-7.5) |
| | | 3-Morpholino-2-hydroxypropanesulfonic acid |
| | | (MOPSO, pH 6.2-7.6) |
| | | 1,3-Bis[tris(hydroxymethyl)methylamino]propane |
| | | (Bis-Tris Propane, pH 6.3-9.5) |
| | | N,N-Bis(2-hydroxyethyl)-2-aminoethanesulfonic acid |
| | | (BES, pH 6.4-7.8) |
| | | 3-(N-Morpholino)propanesulfonic acid (MOPS, pH |
| | | 6.5-7.9) |
| | | N-[Tris(hydroxymethyl)methyl]-2- |
| | | aminoethanesulfonic acid (TES, pH 6.8-8.2) |
| | | N-(2-Hydroxyethyl)piperazine-N′-(2-ethanesulfonic |
| | | acid) (HEPES, pH 6.8-8.2) |
| | | 3-(N,N-Bis[2-hydroxyethyl]amino)-2- |
| | | hydroxypropanesulfonic acid (DIPSO, pH 7.0-8.2) |
| | | 4-(N-Morpholino)butanesulfonic acid (MOBS, pH |
| | | 6.9-8.3) |
| | | N-[Tris(hydroxymethyl)methyl]-3-amino-2- |
| | | hydroxypropanesulfonic acid (TAPSO, pH 7.0-8.2) |
| | | 2-Amino-2-(hydroxymethyl)-1,3-propanediol (Tris, |
| | | pH 7.0-9.0) |
| | | 4-(2-Hydroxyethyl)piperazine-1-(2- |
| | | hydroxypropanesulfonic acid) (HEPPSO, pH 7.1-8.5) |
| | | Piperazine-N,N′-bis(2-hydroxypropanesulfonic acid) |
| | | (POPSO, 7.2-8.5), Triethanol amine (TEA, pH 7.3- |
| | | 8.3) |
| | | N-(2-Hydroxyethyl)piperazine-N′-(3-propanesulfonic |
| | | acid) (EPPS, pH 7.3-8.7) |
| | | N-[Tris(hydroxymethyl)methyl]glycine (Tricine, pH |
| | | 7.4-8.8) |
| | | Glycyl-glycine (Gly-Gly, pH 7.5-8.9) |
| | | N,N-Bis(2-hydroxyethyl)glycine (Bicine, pH 7.6-9.0) |
| | | N-(2-Hydroxyethyl)piperazine-N′-(4-butanesulfonic |
| | | acid) (HEPBS, pH 7.6-9.0) |
| | | N-[Tris(hydroxymethyl)methyl]-3- |
| | | aminopropanesulfonic acid (TAPS, pH 7.7-9.1) |
| | | 2-Amino-2-methyl-1,3-propanediol (AMPD, pH 7.8- |
| | | 9.7) |
| | | N-tris(Hydroxymethyl)methyl-4-aminobutanesulfonic |
| | | acid (TABS, pH 8.2-9.6) |
| | | N-(1,1-Dimethyl-2-hydroxyethyl)-3-amino-2- |
| | | hydroxypropanesulfonic acid (AMPSO, 8.3-9.7) |
| | | 2-(Cyclohexylamino)ethanesulfonic acid, (CHES, pH |
| | | 8.6-10.0) |
| | | 3-(Cyclohexylamino)-2-hydroxy-1-propanesulfonic |
| | | acid (CAPSO, 8.9-10.3) |
| | | 2-Amino-2-methyl-1-propanol (AMP, pH 9.0-10.5) |
| | | 3-(Cyclohexylamino)-1-propanesulfonic acid (CAPS, |
| | | pH 9.7-11.1) |
| | | 4-(Cyclohexylamino)-1-butanesulfonic acid (CABS, |
| | | pH 10.0-11.4) |
| Cu(II) | Stabilize Cu source in | Ethylenediamenetetraacetic acid |
| Ligand | alkaline solution to | Ethylene diamine |
| (Complexer) | prevent hydroxide | Triethanolamine |
| Examples | precipitation | Diethanolamine |
| | | Monoethanolamine |
| | | Oxalate |
| | | Diethylenetriamine |
| | | Diethylenetetramine |
| | | Triethylenetetramine |
| | | Piperazine |
| | | Imidazolidine |
| | | Pyrazolidine |
| | | Glycine |
| | | Iminodiacetic acid |
| | | Nitrilotriacetic acid |
| | | Hydroxethylethylenediaminetriacetic acid |
| | | Dihydroxymethylethylenediaminediacetic acid |
| | | Cyclohexane-1,2-diaminetetracetic acid |
| | | Ethylenebis(oxyethylenenitrilo)tetraacetic acid |
| | | Ethylenediaminetetrapropionic acid |
| | | N,N,N′,N′-tetrakis-2-(2- |
| | | hydroxypropyl)ethylenediamine |
| | | Tartaric acid |
| | | Citric acid |
| | | Gluconic acid |
| | | Succinic acid |
| | | Malic acid |
| | | Succinimide |
| | | Phthalimide |
| | | Hydantoin |
| | | 5,5-dimethylhydantoin |
| | | Amino trimethylene phosphonic acid |
| | | Etidronic acid |
| | | Ethylenediamine tetrakis(methylene phosphonic acid) |
| | | Diethylenetriamine pentamethylene phosphonic acid |
| Cu (I) | Stabilize Cu (I) - for | Triflate |
| Ligand | moderate stability, | Ammonia |
| (Complexer) | encourages Cu (II) | Iodide |
| Examples | reduction by stabilizing a | Bromide |
| | reaction intermediate, for | Chloride |
| | very strong stability | Thiocyanate |
| | hinders Cu(II) reduction | Thiosulfate |
| | by interrupting reaction | Imidazole |
| | pathway | Oxalate |
| | | Aminoacetate |
| | | Methionine |
| | | Cysteine |
| | | Homocysteine |
| | | Taurine |
| | | N-Formylmethionine |
| Sacrificial | Provide side reactions | Hydrogen ion (0 V) |
| Oxidant | which, if more readily | Perbromate (1.745 V) |
| Examples | occurring on the field | Bromate (0.613 V) |
| | than in the feature, can | Hypobromite (0.766 V) |
| | produce fill contrast. | Bromine (1.098 V) |
| | Solution phase reactions | Perchlorate (1.226 V) |
| | at standard reduction | Chlorate (1.130 V) |
| | potentials above about - | Hypochlorate (1.630 V) |
| | 0.2 V are of interest. | Chlorine (1.396 V) |
| | | Iron (III) (0.771 V) |
| | | Iodine (0.620 V) |
| | | Nitrate (0.940 V) |
| | | Dithionate (0.57 V) |
| | | Peroxide (1.763 V) |

In some cases, an alkaline electroplating solution has a pH of about 8 to 10 a copper ion concentration of about 0.4 to 2 g/L, and a combination of accelerator and suppressor. In certain embodiments, such alkaline electroplating solution comprises a thiocyanate salt as an accelerator. In certain embodiments, such alkaline electroplating solution comprises at least one of the following accelerator/suppressor combinations: thiocyanate and polyallylamine, or thiocyanate and polyacrylamide.

An alkaline electroplating solution having any one or more of the just identified accelerator/suppressor combinations may additionally have a leveler, a copper (11) complexer, a copper (I) complexer, a buffer, a pH adjusting component, a sacrificial oxidant, or any combination of these.

Any one or more of copper (II) complexers identified herein may be employed. In certain embodiments, ethylene diamine and/or EDTA are used. Any one or more of copper (I) complexers identified herein may be employed. For example, bromide, chloride, or polyatomic pseudohalides may be used. Any one or more of buffers or pH adjusting components identified herein may be employed. In some embodiments, ammonium hydroxide is used to adjust pH higher. Any one or more of the sacrificial oxidants identified herein may be employed. In some embodiments, nitrate is used as a sacrificial oxidant.

Process Flow

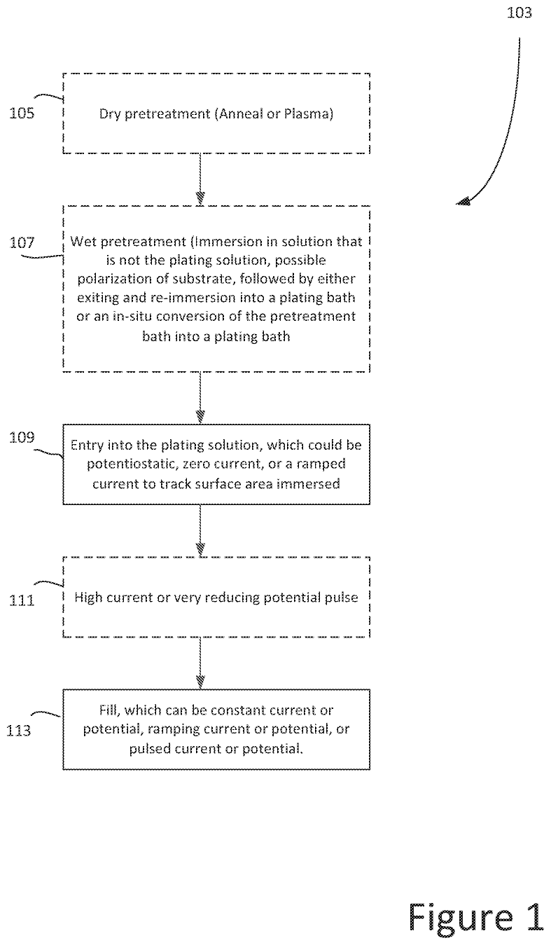

FIG. 1 depicts a simple process flow 103 containing some steps that may be employed in an electroplating process using an alkaline electroplating solution such as any of those disclosed herein. Process flow 103 begins with an optional operation 105 that provides a pretreatment of the substrate to be electroplated. In the depicted embodiment, this pretreatment is a dry pretreatment which may be implemented, for example, as a high temperature anneal, a plasma treatment, or other operation that does not involve contacting the substrate with a liquid. In certain embodiments, the dry pretreatment is performed in a manner that reduces an oxide on a conductive liner of the substrate, e.g., it reduces cobalt oxide on cobalt metal. As an example, an oxide-reducing dry pretreatment involves contacting a substrate with a reducing plasma, such as a hydrogen-containing plasma.

In an optional process operation 107, the substrate is subjected to a wet pretreatment that involves contacting the substrate, or at least a surface of the substrate, with a liquid. In certain embodiments, the liquid contains a material that provides some protection of a metal liner from removal or degradation upon entry into an alkaline electroplating solution.

After optionally performing one, or both, of the dry and wet pretreatments, the substrate is immersed in an alkaline electroplating solution. This may be the operation in which a metal liner or conductive liner is most susceptible to attack. The wet pretreatment and/or dry pretreatment may provide some measure of protection against this attack. Additionally, or alternatively, during immersion, the substrate may be electrically controlled such as by preventing current flow between the substrate and the electrolyte or by cathodically biasing the substrate and thereby reducing the risk of attack by the electroplating solution.

Next, in an operation 111, the substrate is optionally exposed to a high current or a strongly reducing potential pulse. Such operation may be performed for the purpose of, e.g., facilitating nucleation on feature walls during the initial stage of electroplating.

Finally, at an operation 113, the method electrofills features on the substrate with copper. This electroplating operation is optionally conducted with a constant current or potential, or a ramping current or potential, and/or a pulsed current or potential.

Pretreatment

The condition of an incoming substrate influences the quality of a metal film electroplated on the substrate. Pretreatment of the substrate is one way to facilitate electroplating of suitable films. As the name suggests, a pretreatment is a process performed on a substrate to be electroplated prior to immersion in an electroplating solution.

Examples of dry pretreatment processes include annealing and plasma treatments. Examples of wet pretreatment processes include dissolution, pre-functionalization and in-situt oxide reduction. Some of these techniques may be used in combination.

Dry pretreatment processes may improve a conductive liner (or other part of the substrate) by improving the liner's purity, surface functionality, and/or conductivity prior to introduction to the electroplating solution.

An anneal process heats the substrate in a controlled atmosphere for a controlled time, then cools the substrate. In some cases, after the anneal, the substrate is exposed to a normal atmosphere. In one example, an anneal process involves heating the substrate to a temperature of about 30 to 600 degrees Celsius for a time of about 30 seconds to one hour. Examples of the atmosphere for the anneal process may be forming gas, containing, e.g., between about 0 and 5% hydrogen by volume with the remainder of the atmosphere containing nitrogen. The atmosphere for the anneal process may also be provided at a substantially or moderately reduced pressure, ranging from, e.g., about 10⁹ Torr to 760 Torr. In some cases, the atmosphere may comprise one or more inert gases such as helium, argon, and/or nitrogen. In some cases, the atmosphere may consist of solely one or more inert gas such as helium, argon, and/or nitrogen.

In some embodiments, a dry pretreatment employs a plasma to alter the surface of the substrate. A plasma process may reduce oxide on the surface of the substrate. Some such processes employ a reducing plasma. In certain embodiments, the plasma is generated from a gas mixture of hydrogen and a carrier, such as helium. The pressure of the gas mixture may be about 0.1 to 10 Torr, for example about 1 to 3 Torr. A plasma is struck in the gas mixture using, e.g., radio frequency energy input having a power of, e.g., about 0.25 to 5 kW, for example about 1 to 3 kW. In certain embodiments, a plasma generation chamber may be separated from the substrate by a perforated barrier (e.g., a showerhead) which may be grounded and cooled to decrease ion flux while permitting hydrogen radical flux. During processing, the substrate may rest on a heated pedestal under a showerhead. Examples of remote plasma systems are described in U.S. Pat. No. 9,865,501, issued Jan. 9, 2018, which is incorporated herein by reference in its entirety.

In certain plasma pretreatment embodiments, the temperature of substrate (optionally through control of the pedestal temperature) is held at about 30 degrees Celsius to 600 degrees Celsius, for example about 75 to 250 degrees Celsius. In certain embodiments, a plasma pretreatment is performed for a period of about 30 seconds to 60 minutes. The substrate may be cooled before being allowed to contact normal atmosphere.

Further examples of dry pretreatments that may be employed prior to electroplating with an alkaline electroplating solution as disclosed herein are presented in U.S. Pat. No. 9,070,750, issued Jun. 30, 2015, U.S. Pat. No. 9,865,501, issued Jan. 9, 2018, US Patent Application Publication No. 2015/0299886, published Oct. 22, 2015, and US Patent Application Publication No. 2015/0376792, published Dec. 31, 2015, each of which is incorporated herein by reference in its entirety.

A wet pretreatment may be used alone or combined with dry pretreatment. As an example, pretreatment prior to immersion in the electroplating solution may involve first annealing and/or plasma treatment the substrate followed by immersion of the substrate in a pretreatment bath for, e.g., about 1 to 600 seconds.

One type of wet pretreatment involves removing unwanted materials, which may be in the form of layers of material, from the substrate. An example of such wet pretreatment is descumming the surface an incoming substrate using an organic solvent, a mixture of organic solvents, or mixtures of organic solvents with water. As an example, a descumming pretreatment may be performed using isopropyl alcohol, ethanol, acetone, toluene, benzene, or other solvents familiar to those of ordinary skilled in descumming. Descumming is described in, for example, Menon, V. B., et al. (1989), Particle Removal from Semiconductor Wafers Using Cleaning Solvents, in: Mittal, K. L. (ed) Particles in Gases and Liquids 1, pp. 259-271, Springer, Boston, Mass.

In some embodiments, a wet pretreatment dissolves an incoming oxide or other surface layer. The choice of pretreatment liquid depends on the substrate and material to be removed. In some cases, the pretreatment employs an acidic solution, for example sulfuric acid, hydrochloric acid, or other acid in solution and providing a pH between 1 and 7.

In some embodiments, a wet pretreatment adds material to or alters the surface of the substrate through, e.g., pre-functionalization. In some cases, such wet pretreatment introduces a suppressor, accelerator, leveler, copper, ligand, buffer species, or any combination thereof to the substrate before immersion in the electroplating solution. This pretreatment may allow the included molecules (of the pretreatment solution) to interact with the substrate without competition from other molecules used in the alkaline electroplating solution that are absent from the pretreatment bath. In some cases, this process allows additives to set up within substrate features and/or on field regions in a way that promotes a particular electrofill characteristic, at least early in the plating process.

In certain embodiments, a wet pretreatment reduces an oxide on a substrate in situ. In some examples, a substrate is immersed in a pretreatment electrolyte bath containing no additives. During or after immersion, but prior to electroplating, a reducing potential is applied to the substrate. Such potential may be less negative than that of water, such that the solvent is not electrolytically split. The reducing potential may reduce the native oxide on the surface of the substrate, creating an improved surface for nucleation during the subsequent electroplating operation. In certain embodiments, the reducing pretreatment is performed in a manner that does not electroplate metal onto the substrate.

In all wet pretreatment processes, the pretreatment may occur in a bath separate from the electroplating cell, or it may occur in the same cell but in a way that changes the composition of the bath over time. If the pretreatment occurs in a separate cell or other vessel, the substrate may be removed from the pretreatment bath and either rinsed or immediately immersed into the electroplating solution. In some embodiments in which the pretreatment occurs in a vessel where the solution composition changes from a pretreatment composition to an electroplating composition, some or all components of the pretreatment bath may be present at some concentration in the final electroplating solution, and additional components may be added at the conclusion of the pretreatment process. For example, a wet pretreatment may occur in which the substrate is subjected to a reducing potential in a bath containing only the suppressor and a buffer species used in the final electroplating solution. After the end of the pretreatment, a concentrated solution containing copper, accelerator, leveler, ligand, suppressor and buffer, in the appropriate concentrations, may be added to mix with the solution volume of the pretreatment bath. After a reaching a target composition for the electroplating solution, a plating waveform is applied. In some embodiments, the pretreatment bath contains no constituent chemicals not also present in the electroplating solution.

As indicated, in some embodiments, wet protection (performed in situ or ex situ with respect to the plating cell) involves apply a reducing potential to the substrate to reduce the oxide while it is present in the solution. In some implementations, wet reduction of oxide is performed in solution having no metal. In this way, all or much of the reducing current goes to reducing metal oxide on the substrate surface, and little or no current goes to reducing solution phase metal ions, which would be a competing reaction that could produce a mixed oxide and reduced metal layer on the surface. In some embodiments, the substrate is pretreated in a plating chamber initially without plating, but only for oxide reduction. During this initial phase, the wafer is immersed in the plating cell which has a composition resembling the plating electrolyte but without reducible metal ions (e.g., without copper ions), and the wafer is exposed to a reducing potential. After a defined period (time or current or electrical charge passed), metal ions are introduced to the plating cell by, e.g., a bulk transfer of plating solution to the plating cell and driven via, e.g., a pump, and electroplating begins on the now reduced metal liner. During both phases of the process (wet pretreatment and electrofill), the wafer is held at a reducing potential. During the first phase, the current may be relatively low because all charge transfer will occur from the reduction of the thin layer of oxide on the wafer surface. During the second phase, the current will be relatively higher and typical of plating, since charge transfer can now occur with Cu(II) for reduction supplied by the electrolyte.

Further examples and features of wet pretreatments that may be employed prior to electroplating with an alkaline electroplating solution as disclosed herein are presented in US Patent Application No. 2014/0199497, published Jul. 17, 2014, and US Patent Application Publication No. 2015/0299886, published Oct. 22, 2015, each of which is incorporated herein by reference in its entirety.

Plating Process

Substrate Entry

Entry of the substrate into the electroplating solution may be controlled. Depending on the nature of the substrate being plated upon and its interaction with the additives, different entry types may be employed. In some cases, the entry of the wafer into an alkaline electroplating solution can impact nucleation of copper on the substrate. Nucleation plays a role the formation of a good interface between the plated film and the substrate.

A cold entry is a process of immersing a substrate in an alkaline electroplating solution without passing current; particularly in a cold entry, current is not passed across the substrate to the electroplating solution. The potential of the substrate may be allowed to shift while maintaining the no current state. In certain embodiments, the cold entry state is maintained over the course of the substrate's immersion in the electroplating solution, i.e., the time between when the wafer touches the surface of the electroplating solution and when it becomes fully immersed. In some cases, cold entry is maintained for about 0 to 10 seconds, for example for about 0 to 2 seconds.

In some cases, a cold entry allows the electroplating solution to strip an undesired surface coverage from the substrate. In some cases, a cold entry facilitates additive distribution at appropriate locations on the substrate. Such distribution may facilitate subsequent superconformal fill.

In a potentiostatic entry, substrate immersion takes place with a controlled substrate potential of, for example, about 0 to −1.5V relative to the potential of a copper reference electrode or a copper pseudo-reference electrode. This potential is held for an amount of time sufficient for the substrate to become completely immersed in the electroplating solution plus, in some embodiments, an additional amount of time of, for example, about 0 to 10 seconds. In certain embodiments, a potentiostatic entry is used to cathodically protect the substrate, such as in cases where a substrate metal (e.g., a conductive liner) is less noble than copper.

Electrical Waveform

The electrical waveform of plating may have features that facilitate plating high-quality films with good fill in features; e.g., high conductivity copper films that do not have gaps or voids. Current control or potential control may be employed. Potential control may be appropriate for applications in which the surface area of the substrate exposed to solution is changing quickly.

In some embodiments, the waveform is a single constant current applied to the substrate. In some embodiments, the waveform includes increasing the current during, e.g., the first few hundred milliseconds after immersion. This waveform has been found, in some cases, to improve nucleation on substrates. In some embodiments, the waveform applied to the substrate includes ramping the current. Ramping current has been found, in some cases, to produce improved fill by sweeping through a series of currents and potentials such that each feature on the substrate experiences current or potential suitable for superconformal fill for some period. In the case of some fill mechanisms in which the contrast is generated through the slightly higher concentration of certain accelerants or copper ions in the feature relative to the field, pulsing the plating potential may improve fill by iterating a small contrast over many events.

Examples of general types of electrical waveform include: constant current, linear ramping up or down of current, a high current pulse followed by either constant or a linear ramp, long periods of pulsing with a net reductive current, either as the primary mode of fill or punctuated by longer periods of constant current or linear ramps. These waveforms can be under regimes of either current or potential control.

The following provide a few examples of electrical waveforms that may be used with alkaline electroplating solutions. Any one or more of them may be employed in a given electroplating process.
1) during the first about 0 to 10 seconds after immersion, the potential of the substrate is controlled to a point between about 0 to −1.5V relative to a copper pseudoreference electrode.
2) during the first about 1 to 10 seconds after immersion, the current of the part is controlled to about OA and the potential is allowed to drift freely.
3) during a fill period, after immersion, current to the substrate is galvanostatically controlled to a point between about 0.25 mA/cm² and 40 mA/cm². This may be a constant current.
4) during a fill period, after immersion, current to the substrate is galvanodynamically controlled to increase from a low to a high value or from a high to low value. In certain embodiments, the current density is ramped at a rate of about 4 to about 400 mA/cm²·s. As an example, a ramp may range from about 0.25 mA/cm² to about 40 mA/cm² over a period of between 0.1 and 10 seconds.
5) during a fill period, after immersion, current to the substrate is first controlled to a high setpoint, for example between about 1 and 60 mA/cm², for a period of about 0.1 to 10 seconds, before returning to the galvanostatically or galvanodynamically controlled current. In various embodiments, the electroplating waveform comprises an initial high current pulse, such as this.
6) during a fill period, after immersion, current to applied to the substrate via a series of higher and lower current pulses with a net reductive duty cycle. In certain embodiments, this current waveform comprises a series of strong and weak reducing pulses and/or one or more strong reducing pulses with one or more weak oxidative (stripping) pulse.
7) In any of examples 2-6, the recited current control may be replaced with potential control.
8) In any of examples 1-7, in addition to any waveform changes, the rotation rate of the substrate is varied higher or lower during application of the electrical waveform.
9) In any of examples 1-7, in addition to any waveform changes, the flow of fluid through the plating cell is varied higher or lower during application of the electrical waveform.

Mass Transport

Mass transport of alkaline electroplating solution to substrate features may influence electroplating conditions and results. Apart from the selection of solution species, mass transport may, in some cases, be controlled by any one or more of the following operational parameters: (a) the flow rate at which solution is passed through the plating cell, (b) the revolutions per minute (RPM) of the substrate rotating in the plating cell, and (c) the temperature of the electroplating solution, which will affect diffusion of species to the substrate. The flow rate and RPM can be controlled either statically or dynamically during the plating process. To practice static control, a fixed flow and RPM is determined and controlled to that level for the duration of the process. To practice dynamic control, flow and/or RPM is varied during the process to produce different mass transport regimes appropriate for different phases of the electroplating plating. For example, during fill it may be beneficial to have low convection, diffusion limited transport of leveler or sacrificial oxidant to encourage contrast between the field and the features, while during the electroplating of an overburden step it may be beneficial to have high flow and/or RPM to support high limiting currents and increase throughput of the process.

Apparatus

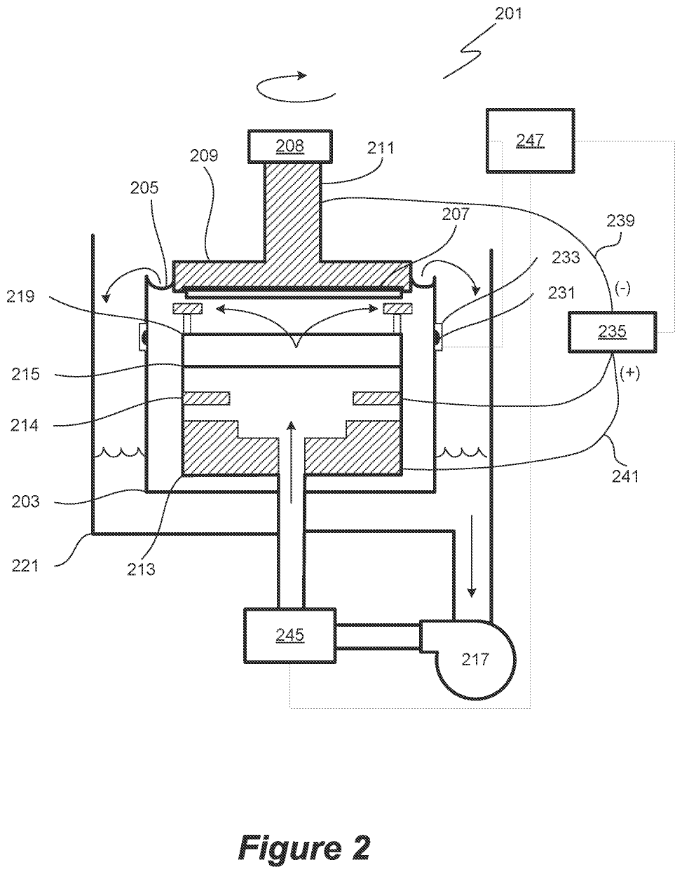

FIG. 2 presents an example of a single electroplating cell 201 that may be employed to electroplate copper. In certain embodiments, cell 201 may serve as one of cells in an electroplating platform. Additives (e.g., accelerators, suppressors, and/or levelers) added to the electrolyte may react with the anode in undesirable ways. Therefore, anodic and cathodic regions of the electroplating cell are sometimes separated by a membrane so that plating solutions of different composition may be used in each region. Electroplating solution in the cathodic region is called catholyte; and in the anodic region, anolyte. A number of engineering designs can be used in order to introduce anolyte and catholyte into the plating apparatus.

Referring to FIG. 2, a diagrammatical cross-sectional view of the electroplating apparatus 201 in accordance with one embodiment is shown. An electroplating bath 203 is shown at a level 205. A catholyte portion of this vessel is adapted for receiving substrates in a catholyte. A wafer 207 is immersed into the plating solution and is held by, e.g., a “clamshell” substrate holder 209, mounted on a rotatable spindle 211, which allows rotation of clamshell substrate holder 209 together with the wafer 207. A general description of a clamshell-type plating apparatus having aspects suitable for use with this invention is described in detail in U.S. Pat. No. 6,156,167 issued to Patton et al., and U.S. Pat. No. 6,800,187 issued to Reid et al., which are incorporated herein by reference in their entireties.

An anode 213 is disposed below the wafer within the electroplating bath 203 and is separated from the wafer region by a membrane 215 such as an ion selective membrane. These membranes may be made of ionomeric materials, such as perfluorinated co-polymers containing sulfonic groups (e.g. Nafion™), sulfonated polyimides, and other materials known to those of skill in the art to be suitable for cation exchange. Examples of suitable Nafion™ membranes include N324 and N424 membranes available from Dupont de Nemours Co. The region below the anodic membrane is often referred to as an “anode chamber.” The ion-selective anode membrane 215 allows ionic communication between the anodic and cathodic regions of the plating cell, while preventing the particles generated at the anode from entering the proximity of the wafer and contaminating it. The anode membrane may distribute current flow during the plating process and thereby improving the plating uniformity. Detailed descriptions of suitable anodic membranes are provided in U.S. Pat. Nos. 6,146,798 and 6,569,299 issued to Reid et al., both incorporated herein by reference in their entireties.

During electroplating the ions from the plating solution are reduced on the substrate. The metal ions must diffuse through the diffusion boundary layer and into the TSV hole or other feature. A typical way to assist the diffusion is through convection flow of the electroplating solution provided by the pump 217. Additionally, a vibration agitation or sonic agitation member may be used as well as wafer rotation. For example, a vibration transducer 208 may be attached to the clamshell substrate holder 209.

The electroplating solution is continuously provided to bath 203 by the pump 217. In certain embodiments, the plating solution flows upwards through an anode membrane 215 and a diffuser plate 219 to the center of wafer 207 and then radially outward and across wafer 207. The electroplating solution also may be provided into the anodic region of the bath from the side of the plating bath 203. The electroplating solution then overflows plating bath 203 to an overflow reservoir 221. The electroplating solution is then filtered (not shown) and returned to pump 217 completing the recirculation of the plating solution. In certain configurations of the plating cell, a distinct electrolyte is circulated through the portion of the plating cell in which the anode is contained while mixing with the main plating solution is prevented using sparingly permeable membranes or ion selective membranes.

A reference electrode 231 is located on the outside of the plating bath 203 in a separate chamber 233, which chamber is replenished by overflow from the main plating bath 203. Alternatively, in some embodiments the reference electrode is positioned close to the substrate surface, and the reference electrode chamber is connected via a capillary tube or by another method, to the side of the wafer substrate or directly under the wafer substrate. The reference electrode 231 may be one of a variety of commonly used types such as mercury/mercury sulfate, silver chloride, saturated calomel, or copper metal. A contact sense lead in direct contact with the wafer 207 may be used in some embodiments, in addition to the reference electrode, for potential measurement (not shown). In some embodiments, contact sense leads connect to the wafer periphery and are configured to sense the potential of the metal seed layer at the periphery of the wafer but do not carry any current to the wafer.

A DC power supply 235 can be used to control current flow to the wafer 207. The power supply 235 has a negative output lead 239 electrically connected to wafer 207 through one or more slip rings, brushes and contacts (not shown). The positive output lead 241 of power supply 235 is electrically connected to an anode 213 located in plating bath 203. The power supply 235, the reference electrode 231, and a contact sense lead (not shown) can be connected to a system controller 247, which allows, among other functions, modulation of current and potential provided to the elements of electroplating cell. For example, the controller may allow electroplating in potential-controlled and/or current-controlled regimes. The controller may include program instructions specifying current and voltage levels that need to be applied to various elements of the plating cell, as well as times at which these levels need to be changed. When forward current is applied, the power supply 235 biases the wafer 207 to have a negative potential relative to anode 213. This causes an electrical current to flow from anode 213 to the wafer 207, and an electrochemical reduction reaction occurs on the wafer surface (the cathode), which results in the deposition of the electrically conductive layer (e.g. copper) on the surfaces of the wafer. An inert or active anode 214 may be installed below the wafer 207 within the electroplating bath 203 and separated from the wafer region by the membrane 215.

The apparatus may also include a heater 245 for maintaining the temperature of the electroplating solution at a specific level. The electroplating solution may be used to transfer the heat to the other elements of the plating bath. For example, when a wafer 207 is loaded into the plating bath the heater 245 and the pump 217 may be turned on to circulate the electroplating solution through the electroplating apparatus 201, until the temperature throughout the apparatus becomes substantially uniform. In one embodiment the heater is connected to the system controller 247. The system controller 247 may be connected to a thermocouple to receive feedback of the plating solution temperature within the electroplating apparatus and determine the need for additional heating.

The controller will typically include one or more memory devices and one or more processors. The processor may include a CPU or computer, analog and/or digital input/output connections, stepper motor controller boards, etc. In certain embodiments, the controller controls all activities of the electroplating apparatus. Non-transitory machine-readable media containing instructions for controlling process operations in accordance with the present embodiments may be coupled to the system controller.

In certain embodiments, there will be a user interface associated with controller 247. The user interface may include a display screen, graphical software displays of the apparatus and/or process conditions, and user input devices such as pointing devices, keyboards, touch screens, microphones, etc. The computer program code for controlling electroplating processes can be written in any conventional computer readable programming language: for example, assembly language, C, C++, Pascal, Fortran or others. Compiled object code or script is executed by the processor to perform the tasks identified in the program. One example of a plating apparatus that may be used according to the embodiments herein is the Lam Research Sabre tool. Electrodeposition can be performed in components that form a larger electrodeposition apparatus.

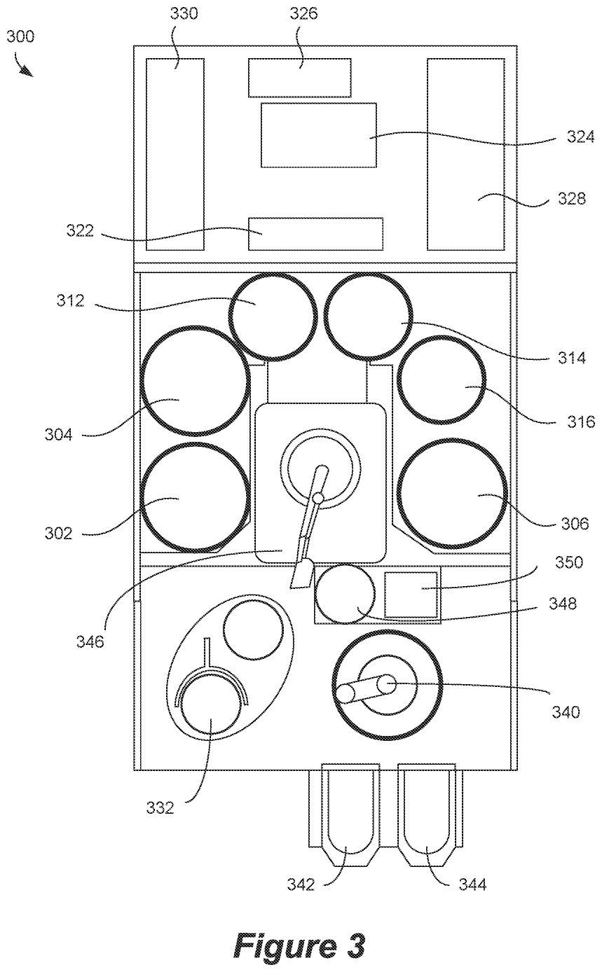

FIG. 3 shows a schematic of a top view of an example electrodeposition apparatus. The electrodeposition apparatus 300 can include three separate electroplating modules 302, 304, and 306. The electrodeposition apparatus 300 can also include three separate modules 312, 314, and 316 configured for various process operations. For example, in some embodiments, one or more of modules 312, 314, and 316 may be a spin rinse drying (SRD) module. In other embodiments, one or more of the modules 312, 314, and 316 may be post-electrofill modules (PEMs), each configured to perform a function, such as edge bevel removal, backside etching, and acid cleaning of substrates after they have been processed by one of the electroplating modules 302, 304, and 306.

The electrodeposition apparatus 300 includes a central electrodeposition chamber 324. The central electrodeposition chamber 324 is a chamber that holds the chemical solution used as the electroplating solution in the electroplating modules 302, 304, and 306. The electrodeposition apparatus 300 also includes a dosing system 326 that may store and deliver additives for the electroplating solution. A chemical dilution module 322 may store and mix chemicals to be used as an etchant. A filtration and pumping unit 328 may filter the electroplating solution for the central electrodeposition chamber 324 and pump it to the electroplating modules.

A system controller 330 provides electronic and interface controls required to operate the electrodeposition apparatus 300. The system controller 330 (which may include one or more physical or logical controllers) controls some or all the properties of the electroplating apparatus 300.

Signals for monitoring the process may be provided by analog and/or digital input connections of the system controller 330 from various process tool sensors. The signals for controlling the process may be output on the analog and digital output connections of the process tool. Non-limiting examples of process tool sensors that may be monitored include mass flow controllers, pressure sensors (such as manometers), thermocouples, optical position sensors, etc. Appropriately programmed feedback and control algorithms may be used with data from these sensors to maintain process conditions.

A hand-off tool 340 may select a substrate from a substrate cassette such as the cassette 342 or the cassette 344. The cassettes 342 or 344 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 340 may hold the substrate using a vacuum attachment or some other attaching mechanism.

The hand-off tool 340 may interface with a wafer handling station 332, the cassettes 342 or 344, a transfer station 350, or an aligner 348. From the transfer station 350, a hand-off tool 346 may gain access to the substrate. The transfer station 350 may be a slot or a position from and to which hand-off tools 340 and 346 may pass substrates without going through the aligner 348. In some embodiments, however, to ensure that a substrate is properly aligned on the hand-off tool 346 for precision delivery to an electroplating module, the hand-off tool 346 may align the substrate with an aligner 348. The hand-off tool 346 may also deliver a substrate to one of the electroplating modules 302, 304, or 306 or to one of the three separate modules 312, 314, and 316 configured for various process operations.

An example of a process operation according to the methods described above may proceed as follows: (1) electrodeposit copper or another material onto a substrate in the electroplating module 304; (2) rinse and dry the substrate in SRD in module 312; and, (3) perform edge bevel removal in module 314.

An apparatus configured to allow efficient cycling of substrates through sequential electroplating, rinsing, drying, and PEM process operations may be useful for implementations for use in a manufacturing environment. To accomplish this, the module 312 can be configured as a spin rinse dryer and an edge bevel removal chamber. With such a module 312, the substrate would only need to be transported between the electroplating module 304 and the module 312 for the copper plating and EBR operations. In some embodiments the methods described herein will be implemented in a system which comprises an electroplating apparatus and a stepper.

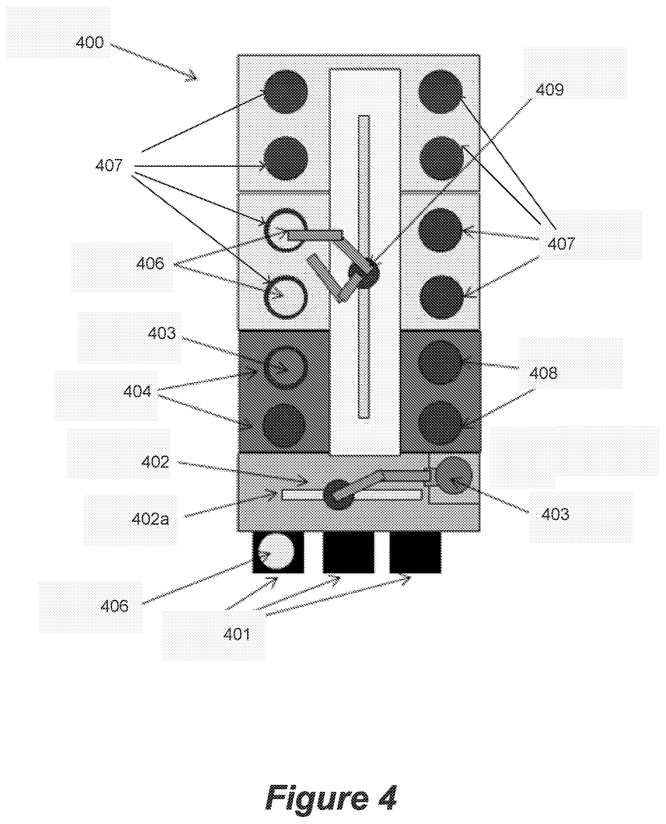

An alternative embodiment of an electrodeposition apparatus 400 is schematically illustrated in FIG. 4. In this embodiment, the electrodeposition apparatus 400 has a set of electroplating cells 407, each containing an electroplating bath, in a paired or multiple “duet” configuration. In addition to electroplating per se, the electrodeposition apparatus 400 may perform a variety of other electroplating related processes and sub-steps, such as spin-rinsing, spin-drying, metal and silicon wet etching, electroless deposition, pre-wetting and pre-chemical treating, reducing, annealing, electro-etching and/or electropolishing, photoresist stripping, and surface pre-activation, for example. The electrodeposition apparatus 400 is shown schematically looking top down in FIG. 4, and only a single level or “floor” is revealed in the figure, but it is to be readily understood by one having ordinary skill in the art that such an apparatus, e.g., the Lam Sabre™ 3D tool, can have two or more levels “stacked” on top of each other, each potentially having identical or different types of processing stations.

Referring once again to FIG. 4, the substrates 406 that are to be electroplated are generally fed to the electrodeposition apparatus 400 through a front end loading FOUP 401 and, in this example, are brought from the FOUP to the main substrate processing area of the electrodeposition apparatus 400 via a front-end robot 402 that can retract and move a substrate 406 driven by a spindle 403 in multiple dimensions from one station to another of the accessible stations-two front-end accessible stations 404 and also two front-end accessible stations 408 are shown in this example. The front-end accessible stations 404 and 408 may include, for example, pre-treatment stations, and spin rinse drying (SRD) stations. Lateral movement from side-to-side of the front-end robot 402 is accomplished utilizing robot track 402a. Each of the substrates 406 may be held by a cup/cone assembly (not shown) driven by a spindle 403 connected to a motor (not shown), and the motor may be attached to a mounting bracket 409. Also shown in this example are the four “duets” of electroplating cells 407, for a total of eight electroplating cells 407. A system controller (not shown) may be coupled to the electrodeposition apparatus 400 to control some or all of the properties of the electrodeposition apparatus 400. The system controller may be programmed or otherwise configured to execute instructions according to processes described earlier herein.

System Controller

In some implementations, a controller is part of a system, which may be used with the above-described apparatus. For example, a system may comprise semiconductor processing equipment, including a processing tool or tools, chamber or chambers, a platform or platforms for processing, and/or specific processing components (a wafer holder, a electrolyte recirculation system, etc.). These systems may be integrated with electronics and/or logic for controlling their operation before, during, and after processing of a semiconductor wafer or substrate. The electronics and/or logic may be referred to as the “controller,” which may control various components or subparts of the system or systems. The controller, depending on the processing requirements and/or the type of system, may be programmed to control any of the processes disclosed herein, including temperature settings (e.g., heating and/or cooling), pressure settings, electrical current and/or potential settings, flow rate settings, fluid delivery settings, rotational speed settings, substrate immersion settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable electroplating solution composition control, enable electroplating, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on an electroplating system in communication with one or more integrated circuits located remotely (such as at the platform level or as part of a remote computer) that combine to control a process on the chamber.

Without limitation, example systems may include a metal electroplating cell or module, a spin-rinse chamber or module, a bevel edge etch chamber or module, a plasma etch chamber or module, a deposition chamber or module, a clean chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a fabrication facility, a main computer, another controller, or tools used in material transport that bring containers of wafers to and from tool locations and/or load ports in a semiconductor device manufacturing facility.

### Examples

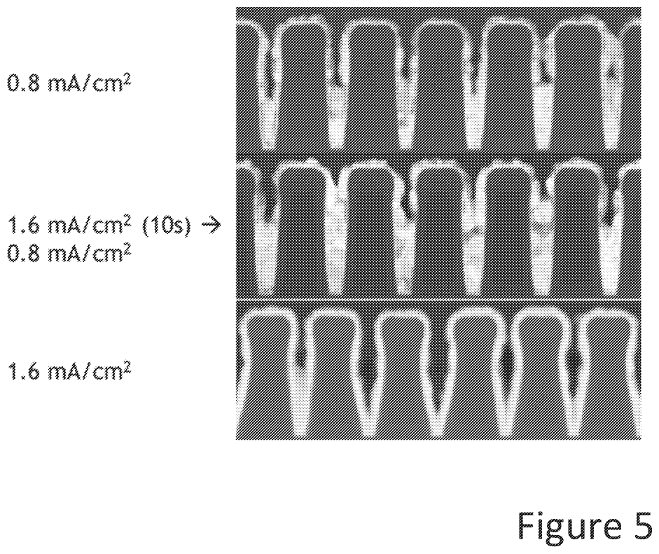

FIG. 5 presents an example of fill profiles illustrating the effect of electrical waveforms, specifically, of an initial high current pulse. The figure shows electron micrographs of microfabricated trench cross sections electroplated with copper. If no high current is applied (0.8 mA/cm2 in this example), nucleation, in this example, was observed to be poor, as seen in the top image. If higher current (1.6 mA/cm2 in this example) is applied for the duration of fill, conformal plating results but nucleation is only acceptable. In this example, the best result can be had by nucleating at high current and filling at low current. See the middle image.

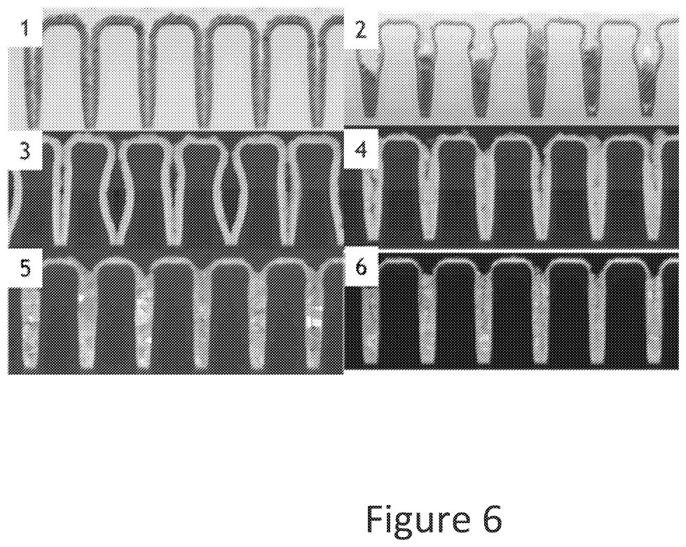

In these tests, the substrate included a cobalt liner substrate with an open dimension of about 20 nm. Each solution displayed here had a pH of about 9 and used a 2:1 molar ratio of ethylene diamine (complexer) to Cu (II), a 0.5 g/L Cu concentration (from CuSO₄), and no leveler or sacrificial oxidant FIG. 6 presents electron micrographs of microfabricated trench cross sections partially electroplated with copper. When the fill is partial, the amount of copper metal inside the feature compared to the amount on top of the field is an initial indicator of the quality of fill, with thin field and thick bottom plating being desired. Each solution displayed here had a pH of about 9 and used a 2:1 molar ratio of ethylene diamine vs. Cu (II) as the Cu (II) complexer, a 0.5 g/L Cu concentration (from CuSO₄), no leveler or sacrificial oxidant, and the following accelerator/suppressor pairs. Image 1 uses benzotriazole as suppressor with no accelerator, and image 2 adds ammonium thiocyanate as accelerator. Image 3 uses high molecular weight polyacrylamide as suppressor with no accelerator, and image 4 adds ammonium thiocyanate as accelerator. Image 5 uses polyallylamine as suppressor with no accelerator, and image 6 adds ammonium thiocyanate as accelerator. Thiocyanate can serve as a Cu(I) complexer. In all three systems, fill is more pronounced with the addition of the accelerator. In some systems, the accelerator addition causes worse nucleation.

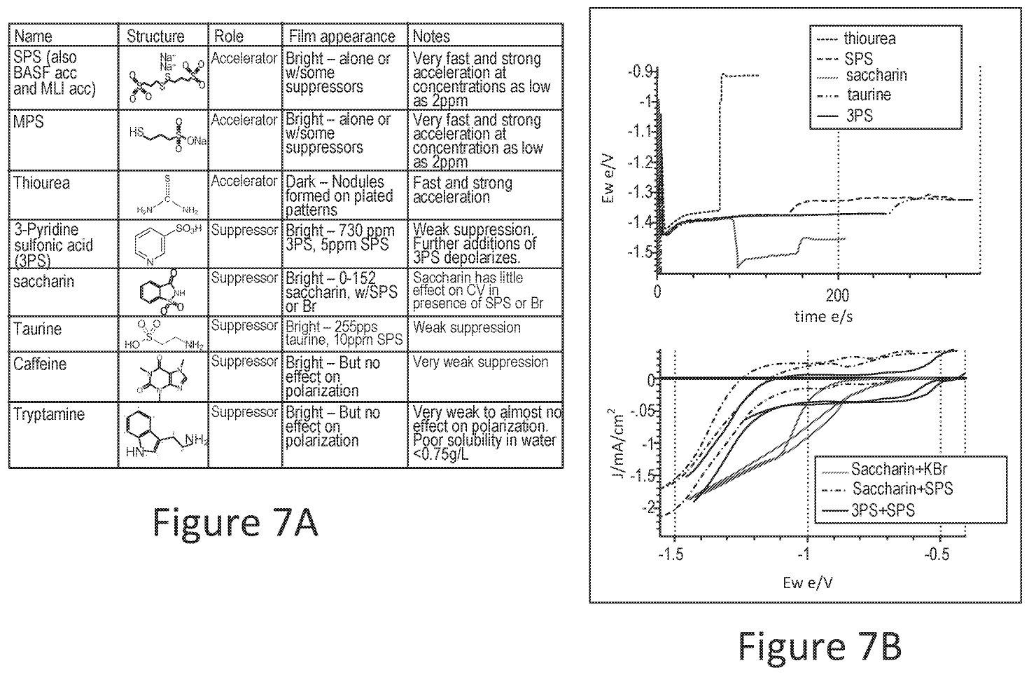

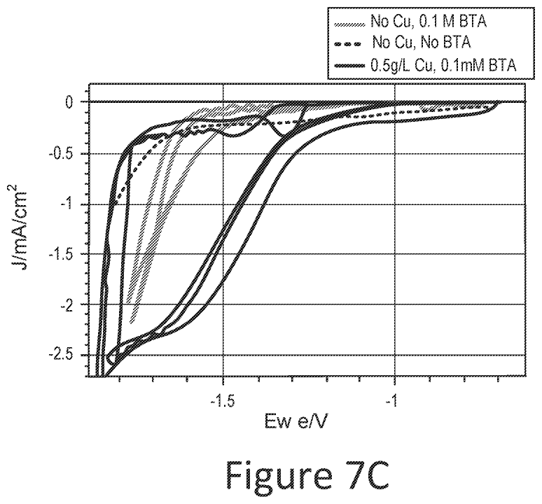

FIGS. 7A, 7B, and 7C illustrate results of two electrochemical techniques for additive screening. FIG. 7A is a composite polarization chart for a few organic additives. Copper metal was allowed to plate onto a test substrate at constant current, and at some time x, the additive is dosed in. Thiourea showed very fast, very strong acceleration. Saccharin showed very strong, very fast suppression. SPS and taurine showed weak, slow acceleration. The x time value of dosing was not consistent in these screenings, it is based on observing a relatively steady state polarization.

The charts in the lower portion of FIG. 7B and FIG. 7C are cyclic voltammograms. The substrate was immersed at its rest potential, then the potential was ramped toward stronger reduction. Once it reached a setpoint, the potential turned around and was ramped back. Additives exhibiting a large gap between the forward and reverse scans indicate a large difference in activity between the suppressed and accelerated surfaces. This may be useful for superconformal fill. The 0.1 mM BTA cyclic voltammogram presents an example of a strong hysteresis signal. Hysteresis is necessary for fill, but not sufficient; if the delta between the two scans cannot be achieved on the field versus the feature, the hysteresis is irrelevant.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of electroplating a metal into features of a substrate, the method comprising:
contacting a substrate with an electroplating solution comprising:
an aqueous solution of pH greater than 7,
about 0.1 to 60 g/L copper salt dissolved in the aqueous solution,
a copper (II) complexing ligand, and
combination of a suppressor and an accelerator selected from the group consisting of (i) a polyallylamine (suppressor) and thiourea (accelerator); (ii) polyallylamine (suppressor) and ammonium thiocyanate (accelerator), and (iii) saccharin (suppressor) and thiourea (accelerator); and
electroplating copper metal from the electroplating solution into features of the substrate.

2. A method of electroplating a metal into features of a substrate, the method comprising:
contacting a substrate with an electroplating solution comprising:
an aqueous solution of pH greater than 7,
about 0.1 to 60 g/L copper salt dissolved in the aqueous solution,
a copper (II) complexing ligand,
an accelerator comprising a thiocyanate salt; and
a suppressor; and
electroplating copper metal from the electroplating solution into features of the substrate.

3. The method of claim 1, wherein electroplating copper metal comprises a superconformal fill of the copper metal into the features of the substrate.

4. The method of claim 1, wherein electroplating copper metal is performed while rotating the substrate in the electroplating solution.

5. The method of claim 1, wherein electroplating copper metal is performed while flowing the electroplating solution through a cell containing the substrate.

6. The method of claim 1, further comprising, prior to contacting the substrate with the electroplating solution, annealing the substrate in inert or reducing atmosphere at a temperature of about 30 to 600 degrees C. for a period of about 30 seconds to one hour.

7. The method of claim 1, further comprising, prior to contacting the substrate with the electroplating solution, annealing the substrate in the presence of a remote reducing plasma while heated the substrate a temperature about 30 C to 600 C for a period of about 30 seconds to one hour.

8. The method of claim 1, further comprising, prior to contacting the substrate with the electroplating solution, contacting the substrate with a pretreatment bath for about 1 to 600 seconds.

9. The method of claim 8, further comprising electrically polarizing the substrate in the pretreatment bath.

10. The method of claim 8, wherein the pretreatment bath contains no constituent chemicals not also present in the electroplating solution.

11. The method of claim 10, further comprising, after a pretreatment period of time, modifying the composition of the pretreatment bath to produce the electroplating solution.

12. The method of claim 1, wherein the electroplating fills features of the substrate having a critical dimension of about 20 nm or less.

13. The method of claim 1, wherein the features of the substrate comprise a diffusion barrier that is about 1 to 5 nm thick.

14. The method of claim 13, wherein the diffusion barrier comprises a tantalum nitride.

15. The method of claim 1, wherein the features of the substrate comprise a conductive liner that is about 1 to 5 nm thick.

16. The method of claim 15, wherein the conductive liner comprises cobalt, molybdenum, titanium, or any combination thereof.

17. The method of claim 1, further comprising, after contacting the substrate with the electroplating solution, holding the substrate at an electrical potential of about 0 to about −1.5V relative to a copper pseudoreference electrode.

18. The method of claim 17, wherein the substrate is held at the electrical potential of about 0 to −1.5V relative to a copper pseudoreference electrode for a time of about 0 to about 10 seconds.

19. The method of claim 1, further comprising, after contacting the substrate with the electroplating solution, controlling current so about 0 A flows between the substrate and the electroplating solution.

20. The method of claim 1, wherein electroplating copper metal comprises controlling current to provide a current density on an electroplating face of the substrate of about 0.25 mA/cm² to about 40 mA/cm².

21. The method of claim 1, wherein electroplating copper metal comprises controlling current between the substrate and the electroplating solution such that the current increases from a low value to a high value or decreases from a high value to low value.

22. The method of claim 21, wherein the current is controlled to provide a current density on an electroplating face of the substrate of about 1 to about 60 mA/cm² for a period of about 0.1 to about 10 seconds, and then decreasing the current density on the electroplating face of the substrate.

23. The method of claim 1, wherein electroplating copper metal comprises controlling current between the substrate and the electroplating solution using a series of current pulses.

24. The method of claim 1, wherein electroplating copper metal comprises controlling the potential of the substrate.

25. An electroplating solution comprising:
an aqueous solution of pH greater than 7;
about 0.1 to 60 g/L Cu(II) supplied as a copper salt dissolved in the aqueous solution;
a copper (II) complexing ligand; and
combination of a suppressor and an accelerator selected from the group consisting of (a) a polyallylamine (suppressor) and thiourea (accelerator); (b) polyallylamine (suppressor) and ammonium thiocyanate (accelerator), and (c) saccharin (suppressor) and thiourea (accelerator).

26. An electroplating solution comprising:
an aqueous solution of pH greater than 7;
about 0.1 to 60 g/L Cu(II) supplied as a copper salt dissolved in the aqueous solution;
a copper (II) complexing ligand;
an accelerator comprising a thiocyanate salt; and
a suppressor.

27. The electroplating solution of claim 25, wherein the copper (II) complexing ligand is present in the aqueous solution at concentration sufficient to prevent copper hydroxide precipitation.

28. The electroplating solution of claim 25, further comprising a pH adjustment agent or buffer sufficient to maintain the pH above 7 during electroplating of copper from the electroplating solution.

29. The electroplating solution of claim 25, further comprising a leveler.

30. The electroplating solution of claim 25, further comprising a copper (I) complexing ligand

31. The electroplating solution of claim 30, further comprising a component that reduces the ability of the copper (I) complexing ligand to prevent Cu(I) reduction during electroplating.

32. The electroplating solution of claim 25, further comprising a sacrificial oxidant.
